(19) United States
(12) Patent Application Publication
(10) Pub. No.: US 2022/0344379 A1
(43) Pub. Date: Oct. 27, 2022

(54) DISPLAY DEVICE

(71) Applicant: Samsung Display Co., LTD., Yongin-si (KR)

(72) Inventors: Hae Ju YUN, Yongin-si (KR); Jin Yeong KIM, Yongin-si (KR); Soo Hyun MOON, Yongin-si (KR); Jun Seok MIN, Yongin-si (KR); Woo Guen JANG, Yongin-si (KR)

(73) Assignee: Samsung Display Co., LTD., Yongin-si (KR)

(21) Appl. No.: 17/576,177

(22) Filed: Jan. 14, 2022

(30) Foreign Application Priority Data
Apr. 26, 2021 (KR) 10-2021-0053879

(51) Int. Cl. H01L 27/12; H01L 25/16

(52) U.S. Cl. CPC H01L 27/1248; H01L 25/167; H01L 27/124; H01L 24/24

(57) ABSTRACT

A display device includes a first pattern and a second pattern, which are spaced apart from each other in an emission area. A light emitting element is disposed between the first pattern and the second pattern. A first electrode is disposed on the first pattern. A second electrode is disposed on the second pattern. A light blocking pattern is disposed under the light emitting element and between the first pattern and the second pattern.

### CROSS-REFERENCE TO RELATED APPLICATION(S)

The application claims priority to and benefits of Korean Patent Application 10-2021-0053879 under 35 U.S.C. § 119, filed on Apr. 26, 2021 in the Korean Intellectual Property Office, the entire contents of which are incorporated herein by reference.

### BACKGROUND

### 1. Technical Field

The disclosure generally relates to a display device.

### 2. Discussion of the Related Art

Recently, interest in information displays has been increased. Accordingly, research and development of display devices has been continuously conducted.

### SUMMARY

Embodiments provide a display device capable of preventing degradation of a transistor due to light advancing toward a rear surface.

In accordance with an aspect of the disclosure, there is provided a display device that may include a first pattern and a second pattern that are spaced apart from each other in an emission area, a first light emitting element disposed between the first pattern and the second pattern, a first electrode disposed on the first pattern, a second electrode disposed on the second pattern, and a light blocking pattern disposed under the first light emitting element and between the first pattern and the second pattern.

The light blocking pattern may include a light blocking material which blocks light emitted from the first light emitting element.

The first pattern and the second pattern may be spaced apart from each other in a first direction. A width of the light blocking pattern in the first direction may be greater than a distance in the first direction between the first electrode and the second electrode, and the width of the light blocking pattern may be smaller than a distance in the first direction between the first pattern and the second pattern.

The light blocking pattern may be disposed on the first electrode and the second electrode and between the first pattern and the second pattern, and the light blocking pattern may cover an area between the first electrode and the second electrode.

The light blocking pattern may not overlap the first pattern and the second pattern. A first inclined surface of the first electrode and a second inclined surface of the second electrode may face each other and may be exposed by the light blocking pattern.

The light blocking pattern may extend to the first electrode, the second electrode, and the first light emitting element.

Each of the first electrode and the second electrode may include a reflective material which reflects light emitted from the first light emitting element.

The display device may further include a transistor and a power line that are disposed under the first pattern and the second pattern, a first pixel electrode electrically connecting a first end portion of the first light emitting element and the transistor to each other, and a second pixel electrode electrically connecting a second end portion of the first light emitting element and the power line to each other.

Each of the first pixel electrode and the second pixel electrode may include a transparent conductive material which allows light emitted from the first light emitting element to be transmitted through the first pixel electrode and the second pixel electrode.

The display device may further include a bank defining the emission area, and a color conversion layer disposed on the first light emitting element in the emission area, the color conversion layer converting a color of light emitted from the first light emitting element.

The light blocking pattern may be disposed under the first electrode and the second electrode, and the light blocking pattern may overlap an area between the first electrode and the second electrode.

The light blocking pattern may be disposed between the first pattern and the second pattern, and the light blocking pattern may extend to the first electrode and the second electrode.

The display device may further include a first insulating layer disposed between the first light emitting element and the light blocking pattern in an area between the first pattern and the second pattern.

The display device may further include a transistor disposed under the first pattern and the second pattern. The light blocking pattern may be disposed between the first and second patterns and the transistor.

The first pattern and the second pattern may be portions of a protective layer at which a top surface of the protective layer protrudes. The light blocking pattern may be disposed between the protective layer and the transistor.

The display device may further include a third pattern spaced apart from the second pattern in the emission area, a second light emitting element disposed between the second pattern and the third pattern, a third electrode disposed on the second pattern, the third electrode having an inclined surface facing a first end portion of the second light emitting element, and a fourth electrode disposed on the third pattern, the fourth electrode having an inclined surface facing a second end portion of the second light emitting element. The light blocking pattern may overlap an area between the second electrode and the third electrode and an area between the third electrode and the fourth electrode.

In accordance with another aspect of the disclosure, there is provided a display device that may include a base layer, a first pattern and a second pattern that may be spaced apart from each other on the base layer in an emission area, a light emitting element disposed between the first pattern and the second pattern, a first electrode disposed on the first pattern, a second electrode disposed on the second pattern, and an insulating layer disposed under the light emitting element and between the first pattern and the second pattern, wherein each of the first electrode and the second electrode includes a reflective material which reflects light emitted from the light emitting element, and a refractive index of the insulating layer may be higher than a refractive index of the base layer.

The refractive index of the insulating layer may be higher than a refractive index of the first pattern and a refractive index of the second pattern.

The display device may further include a first insulating layer disposed between the light emitting element and the insulating layer in an area between the first electrode and the second electrode. The refractive index of the insulating layer may be higher than a refractive index of the first insulating pattern.

The insulating layer may be disposed in a substantially entire area of the emission area.

In accordance with still another aspect of the disclosure, there is provided a display device that may include a first electrode having a first inclined surface, and a second electrode having a second inclined surface facing the first inclined surface, the first electrode and the second electrode being spaced apart from each other in an emission area, a light emitting element disposed between the first inclined surface of the first electrode and the second inclined surface of the second electrode, and a light blocking pattern disposed under the light emitting element in the emission area.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1A is a schematic perspective view illustrating a light emitting element in accordance with an embodiment of the disclosure.

FIGS. 1B to 1D are schematic sectional views illustrating the light emitting element shown in FIG. 1A.

FIG. 2 is a schematic plan view illustrating a display device in accordance with an embodiment of the disclosure.

FIGS. 3A to 3C are schematic circuit diagrams illustrating a pixel included in the display device shown in FIG. 2.

FIG. 4 is a schematic plan view illustrating an embodiment of the pixel included in the display device shown in FIG. 2.

FIG. 5A is a schematic sectional view illustrating an embodiment of the pixel taken along line I-I′ shown in FIG. 4.

FIG. 5B is a schematic sectional view illustrating an embodiment of the pixel shown in FIG. 5A

FIG. 5C is a schematic sectional view illustrating an embodiment of the pixel taken along line II-IF shown in FIG. 4.

FIG. 5D is a schematic sectional view illustrating another embodiment of the pixel taken along the line I-I′ shown in FIG. 4.

FIG. 5E is a schematic sectional view illustrating still another embodiment of the pixel taken along the line I-I′ shown in FIG. 4.

FIGS. 6A to 6D are schematic sectional views illustrating an embodiment of the display device shown in FIG. 2.

FIG. 7 is a schematic sectional view illustrating another embodiment of the pixel included in the display device shown in FIG. 2.

FIG. 8 is a schematic sectional view illustrating still another embodiment of the pixel included in the display device shown in FIG. 2.

FIG. 9 is a schematic sectional view illustrating still another embodiment of the pixel included in the display device shown in FIG. 2.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

As used herein, the singular forms (e.g., a, an, the) are intended to include the plural forms as well (and vice versa), unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

Each embodiment disclosed below may be independently embodied or be combined with at least another embodiment.

In the following embodiments and the attached drawings, elements not directly related to the disclosure may be omitted from depiction, and dimensional relationships among individual elements in the attached drawings may be illustrated only for ease of understanding but not to limit the actual scale.

It will be understood that the terms “connected to” or “coupled to” may include a physical or electrical connection or coupling.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as “not overlapping” or “to not overlap” another element, this may include that the elements are spaced apart from each other, offset from each other, or set aside from each other or any other suitable term as would be appreciated and understood by those of ordinary skill in the art.

“About”, “approximately”, and “substantially” are inclusive of the stated value and mean within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

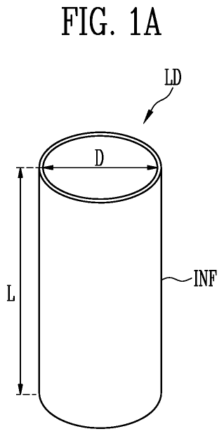

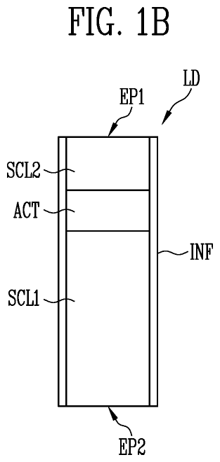

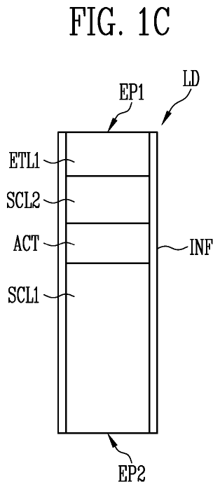

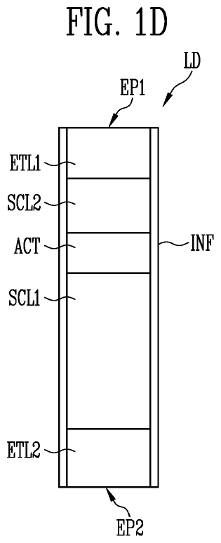

FIG. 1A is a schematic perspective view illustrating a light emitting element in accordance with an embodiment of the disclosure. FIGS. 1B to 1D are schematic sectional views illustrating the light emitting element shown in FIG. 1A. For example, FIGS. 1B to 1D illustrate different embodiments of a configuration of the light emitting element LD shown in FIG. 1A. Although a rod type light emitting element LD having a cylindrical shape is illustrated in FIGS. 1A to 1D, the kind and/or shape of the light emitting element LD is not limited thereto.

Referring to FIGS. 1A to 1D, the light emitting element LD may include a first semiconductor layer SCL1, a second semiconductor layer SCL2, and an active layer ACT interposed between the first and second semiconductor layers SCL1 and SCL2. In an example, the light emitting element LD may include the first semiconductor layer SCL1, the active layer ACT, and the second semiconductor layer SCL2, which may be sequentially stacked on each other along a length L direction.

The light emitting element LD may be provided in a rod shape extending along a direction. When assuming that an extending direction of the light emitting element LD may be the length L direction, the light emitting element LD may have a first end portion EP1 and a second end portion EP2 along the length L direction.

Any one of the first and second semiconductor layers SCL1 and SCL2 may be disposed at the first end portion EP1 of the light emitting element LD. The other of the first and second semiconductor layers SCL1 and SCL2 may be disposed at the second end portion EP2 of the light emitting element LD. In an example, the second semiconductor layer SCL2 may be disposed at the first end portion EP1 of the light emitting element LD, and the first semiconductor layer SCL1 may be disposed at the second end portion EP2 of the light emitting element LD.

In some embodiments, the light emitting element LD may be a rod type light emitting element (also referred to as a “rod type light emitting diode”) manufactured in a rod shape through an etching process, etc. In this specification, the term “rod shape” may include a rod-like shape or bar-like shape, which may be long in the length L direction (i.e., its aspect ratio may be greater than 1), such as a cylinder or a polyprism, and the shape of its section is not particularly limited. For example, a length L of the light emitting element LD may be greater than a diameter D (or a width of a cross-section) of the light emitting element LD.

The light emitting element LD may have a size small to a degree of micrometer scale or nanometer scale. In an example, the light emitting element LD may have a diameter D and/or a length L in a range of micrometer scale or nanometer scales. However, the size of the light emitting element LD is not limited thereto. For example, the size of the light emitting element LD may be variously modified according to design conditions of various types of devices, e.g., a display device and the like, which may use the light emitting element as a light source.

The first semiconductor layer SCL1 may be a first conductivity type semiconductor layer. For example, the first semiconductor layer SCL1 may include an N-type semiconductor layer. In an example, the first semiconductor layer SCL1 may include at least one semiconductor material among InAlGaN, GaN, AlGaN, InGaN, AlN, and InN, and include an N-type semiconductor layer doped with a first conductivity type dopant such as Si, Ge or Sn. The first semiconductor layer SCL1 may be formed of various materials.

The active layer ACT may be formed on the first semiconductor layer SCL1, and may be formed in a single-quantum well structure or a multi-quantum well structure. The position of the active layer ACT may be variously changed according to the kind of the light emitting element LD. The active layer ACT may emit light having a wavelength of about 400 nm to about 900 nm, and use a double hetero-structure.

A clad layer (not shown) doped with a conductive dopant may be formed on the top and/or the bottom of the active layer ACT. In an example, the clad layer may be formed as an AlGaN layer or InAlGaN layer. In some embodiments, a material such as AlGaN or AlInGaN may be used to form the active layer ACT. The active layer ACT may be formed of various materials.

The second semiconductor layer SCL2 may be formed on the active layer ACT, and may include a semiconductor layer having a type different from that of the first semiconductor layer SCL1. For example, the second semiconductor layer SCL2 may include a P-type semiconductor layer. In an example, the second semiconductor layer SCL2 may include at least one semiconductor material among InAlGaN, GaN, AlGaN, InGaN, AlN, and InN, and include a P-type semiconductor layer doped with a second conductivity type dopant such as Mg. The second semiconductor layer SCL2 may be formed of various materials.

In an embodiment, the first semiconductor layer SCL1 and the second semiconductor layer SCL2 may have different lengths (or thicknesses) in the length L direction of the light emitting element LD. In an example, the first semiconductor layer SCL1 may have a length (or thickness) longer (or thicker) than that of the second semiconductor layer SCL2 along the length L direction of the light emitting element LD. Accordingly, the active layer ACT of the light emitting element LD may be located closer to the first end portion EP1 than the second end portion EP2.

In case that a voltage which may be a threshold voltage or higher is applied to both ends of the light emitting element LD, the light emitting element LD emits light while electron-hole pairs are combined in the active layer ACT. The light emission of the light emitting element LD may be controlled by using such a principle, so that the light emitting element LD can be used as a light source for various light emitting devices, including a pixel of a display device.

In an embodiment, the light emitting element LD may further include an additional component, in addition to the first semiconductor layer SCL1, the active layer ACT, and the second semiconductor SCL2. For example, the light emitting element LD may additionally include at least one phosphor layer, at least one active layer, at least one semiconductor layer, and/or at least one electrode layer, which may be disposed at ends of the first semiconductor layer SCL1, the active layer ACT, and/or the second semiconductor layer SCL2.

For example, the light emitting element LD may further include an electrode layer ETL1 disposed at an end of the second semiconductor layer SCL2 as shown in FIG. 1C. The electrode layer ETL1 may be located at the first end portion EP1 of the light emitting element LD.

The light emitting element LD may further include another electrode ETL2 disposed at an end of the first semiconductor layer SCL1 as shown in FIG. 1D. In an example, the electrode layers ETL1 and ETL2 may be disposed at the first and second end portions EP1 and EP2 of the light emitting element LD.

The electrode layers ETL1 and ETL2 may be ohmic contact electrodes, but the disclosure is not limited thereto. For example, the electrode layers ETL1 and ETL2 may be Schottky contact electrodes.

The electrode layers ETL1 and ETL2 may include a metal or metal oxide. In an example, the electrode layers ETL1 and ETL2 may include one or mixture of chromium (Cr), titanium (Ti), aluminum (Al), gold (Au), nickel (Ni), any oxide or alloy thereof, and indium tin oxide (ITO). The electrode layers ETL1 and ETL2 may include the same material or different materials.

The electrode layers ETL1 and ETL2 may be substantially transparent or translucent. Accordingly, light generated in the light emitting element LD may be emitted to the outside of the light emitting element LD by being transmitted through the electrode layers ETL1 and ETL2. In another embodiment, in case that light generated in the light emitting element LD is not transmitted through the electrode layers ETL1 and ETL2 but emitted to the outside of the light emitting element LD through an area except the end portions of the light emitting element LD, the electrode layers ETL1 and ETL2 may be opaque.

In an embodiment, the light emitting element LD may further include an insulative film INF provided on a surface of the light emitting element LD. The insulative film INF may be formed on the surface of the light emitting element LD to surround an outer circumferential surface of at least the active layer ACT. The insulative film INF may further surround areas of the first and second semiconductor layers SCL1 and SCL2.

In case that the light emitting element LD includes the electrode layers ETL1 and ETL2, the insulative film INF may at least partially surround outer circumferential surfaces of the electrode layers ETL1 and ETL2, or may not surround the outer circumferential surfaces of the electrode layers ETL1 and ETL2. For example, the insulative film INF may be selectively formed on surfaces of the electrode layers ETL1 and ETL2.

The insulative film INF may expose the end portions of the light emitting element LD in the length L direction of the light emitting element LD. For example, the insulative film INF may expose at least one of the first and second semiconductor layers SCL1 and SCL2 and the electrode layers ETL1 and ETL2 at the first and second end portions EP1 and EP2 of the light emitting element LD. In other embodiments, the insulative film INF may not be provided in the light emitting element LD.

In case that the insulative film INF is provided to cover the surface of the light emitting element LD, particularly, an outer circumferential surface of the active layer ACT, the insulative film INF may prevent the active layer ACT from being short-circuited with at least one electrode (not shown) (e.g., an alignment electrode and/or a pixel electrode, which will be described later). Accordingly, the electrical stability of the light emitting element LD can be ensured.

The insulative film INF may include a transparent insulating material. For example, the insulative film INF may include at least one insulating material among SiO₂ and silicon oxide (SiOₓ) which may not be fixed thereto, Si₃N₄ or silicon nitride (SiNₓ) which may not be fixed thereto, Al₂O₃ or aluminum oxide (AlₓO_{y}) which may not be fixed thereto, and TiO₂ or titanium dioxide (TiOₓ), but the disclosure is not limited thereto. That is, the material constituting the insulative film INF is not particularly limited.

In case that the insulative film INF is provided on the surface of the light emitting element LD, a surface defect of the light emitting element LD may be minimized, thereby improving the lifespan and efficiency of the light emitting element LD. In case that the insulative film INF is formed in each light emitting element LD, the insulative film INF can prevent an unwanted short circuit occurring between light emitting elements LD even in case that the light emitting elements LD are densely disposed.

In an embodiment of the disclosure, the light emitting element LD may be manufactured through a surface treatment process. For example, in case that light emitting elements LD are mixed in a liquid solution (or solvent) to be supplied to each emission area (e.g., an emission area of each pixel), each light emitting element LD may be surface-treated such that the light emitting elements LD are not unequally condensed in the solution but equally dispersed in the solution. In a non-restrictive embodiment related to this, the insulative film INF itself may be formed as a hydrophobic layer by using a hydrophobic material, or a hydrophobic layer made of a hydrophobic material may be additionally formed on the insulative film.

The insulative film INF may be configured as a single layer or a multi-layer. For example, the insulative film INF may be configured as a double layer.

The insulative film INF may be partially etched in at least one area, e.g., at least one of an upper area and a lower area thereof. The insulative film INF may have a rounded shape in the at least one area thereof, but the disclosure is not limited thereto.

For example, in at least one of an upper area and a lower area of the insulative film INF, the insulative film INF may be partially or entirely removed. Accordingly, at least one of the first semiconductor layer SCL1, the second semiconductor layer SCL2, and the electrode layers ETL1 and ETL2 may be partially exposed.

The light emitting element LD may be used in various types of devices including a display device, which require a light source. For example, in case that light emitting elements LD are disposed in each pixel of a display panel, the light emitting elements LD may be used for a light source of each pixel. However, the application field of the light emitting element LD is not limited to the above-described example. For example, the light emitting element LD may be used for other types of devices that require a light source, such as a lighting device.

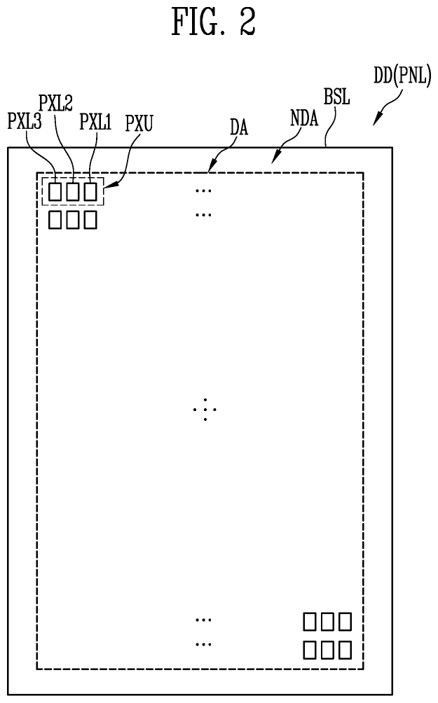

FIG. 2 is a schematic plan view illustrating a display device in accordance with an embodiment of the disclosure. In FIG. 2, a display device DD, particularly, a display panel PNL provided in the display device DD will be illustrated as an example of an electronic device which can use, as a light source, the light emitting element LD described in the embodiments shown in FIGS. 1A to 1D. In an example, each pixel unit PXU of the display panel PNL and each pixel constituting the same may include at least one light emitting element LD.

For convenience, in FIG. 2, a structure of the display panel PNL will be briefly illustrated based on a display area DA. However, in some embodiments, at least one driving circuit (e.g., at least one of a scan driver and a data driver), lines, and/or pads, which are not shown in the drawing, may be further disposed in the display panel PNL.

Referring to FIG. 2, the display panel PNL in accordance with an embodiment of the disclosure may include a base layer BSL and pixels disposed on the base layer BSL. The pixels may include first pixels PXL1, second pixels PXL2, and/or third pixels PXL3. In the description of the embodiment of the disclosure, in case that at least one pixel among the first color pixels PXL1, the second color pixels PXL2, and the third color pixels PXL3 is arbitrarily designated or in case that two or more kinds of pixels among the first color pixels PXL1, the second color pixels PXL2, and the third color pixels PXL3 are inclusively designated, the corresponding pixel or the corresponding pixels will be referred to as a “pixel PXL” or “pixels PXL.”

Specifically, the display panel PNL and the base layer BSL for forming the same may include a display area DA for displaying an image and a non-display area NDA except the display area DA. Pixels PXL may be arranged in the display area DA on the base layer BSL.

The display area DA may be disposed in a central area of the display panel PNL, and the non-display area NDA may be disposed in an edge area of the display panel PNL to surround the display area DA. However, the positions of the display area DA and the non-display area NDA are not limited thereto, and may be changed. The display area DA may constitute a screen on which an image may be displayed, and the non-display area NDA may be the other area except the display area DA.

The base layer BSL may be used to constitute a base member of the display panel PNL, and may be a rigid or flexible substrate or film. In an example, the base layer BSL may be configured as a rigid substrate made of glass or tempered glass, a flexible substrate (or thin film) made of a plastic or metal material, or at least one insulating layer. The material and/or property of the base layer BSL is not particularly limited.

In an embodiment, the base layer BSL may be substantially transparent. The term “substantially transparent” may mean that light can be transmitted with a certain transmittance or higher. In another embodiment, the base layer BSL may be translucent or opaque. In some embodiments, the base layer BSL may include a reflective material.

An area on the base layer BSL may be defined as a display area DA such that pixels PXL may be disposed, and the other area may be defined as a non-display area NDA. In an example, the base layer BSL may include a display area DA including pixel areas in which respective pixels PXL may be formed, and anon-display area NDA disposed at the outside of the display area DA. Various lines, pads, and/or a built-in circuit, which may be connected to the pixels PXL of the display area DA, may be disposed in the non-display are NDA.

Pixels PXL may be arranged in the display area DA. In an example, the pixels PXL may be regularly arranged in the display area DA according to a stripe arrangement structure, a Pentile™ arrangement structure, or the like. However, the arrangement structure of the pixels PXL is not limited thereto, and the pixels PXL may be arranged in the display area DA by using various structures and/or methods.

In some embodiments, two or more kinds of pixels PXL may be disposed emitting lights of different colors. In an example, first color pixels PXL1 emitting light of a first color, second color pixels PXL2 emitting light of a second color, and third color pixels PXL3 emitting light of a third color may be arranged in the display area DA. At least one first color pixel PXL1, a least one second color pixel PXL2, and at least one third color pixel PXL3, which may be disposed adjacent to each other, may constitute a pixel unit PXU capable of emitting lights of various colors. For example, each of the first pixel PXL1, the second pixel PXL2, and the third pixel PXL3 may be a sub-pixel emitting light of a color. In some embodiments, the first pixel PXL1 may be a blue pixel emitting blue light, the second pixel PXL2 may be a green pixel emitting green light, and the third pixel PXL3 may be a red pixel emitting red light. However, the disclosure is not limited thereto.

In an embodiment, the first pixel PXL1, the second pixel PXL2, and the third pixel PXL3 may have, light sources, a light emitting element of a first color, a light emitting element of a second color, and a light emitting element of a third color, to emit lights of the first color, the second color, and the third color, respectively. In another embodiment, the first pixel PXL1, the second pixel PXL2, and the third pixel PXL3 may have light emitting elements emitting light of the same color and include color conversion layers of different colors and/or color filters of different colors, which may be disposed on the light emitting elements, to emit lights of the first color, the second color, and the third color, respectively.

However, the color, kind, and/or number of pixels PXL constituting each pixel unit PXU are not particularly limited. In an example, the color of light emitted by each pixel PXL may be variously changed.

The pixel PXL may include at least one light source driven by a control signal (e.g., a scan signal and a data signal) and/or a power source (e.g., a first power source and a second power source). In an embodiment, the light source may include at least one light emitting element LD in accordance with the embodiments shown in FIGS. 1A to 1D, e.g., at least one rod type light emitting element LD having a size small to a degree of nanometer scale to micrometer scale. Various types of light emitting elements may be used as the light source of the pixel PXL. For example, in another embodiment, a light source of each pixel PXL may be configured by using a light emitting element having a core-shell structure.

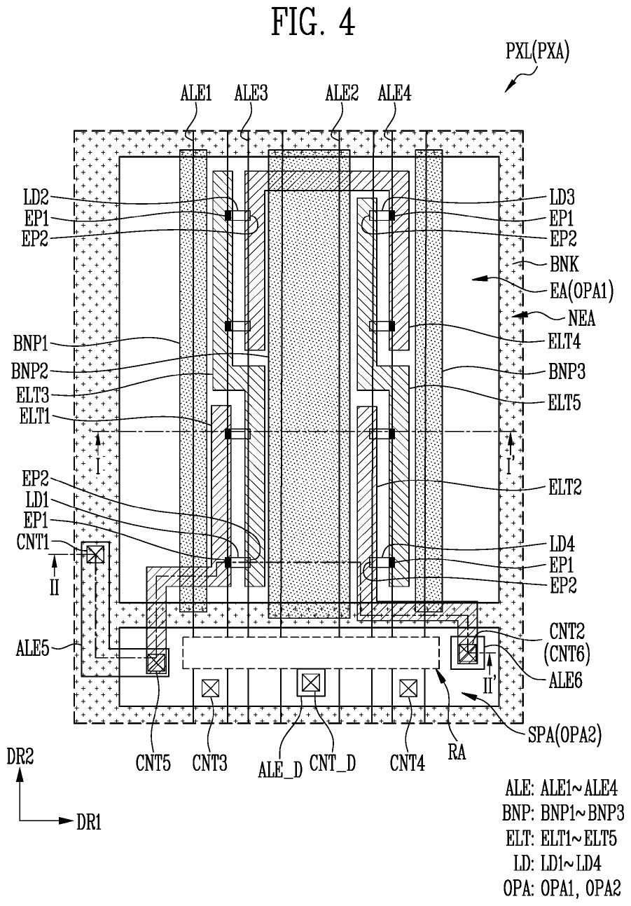

Each pixel PXL may have a structure in accordance with at least one embodiment among various embodiments which will be described hereinafter. For example, each pixel PXL may have a structure in accordance with any embodiment among embodiments disclosed in FIGS. 4 to 9, or have a structure in which multiple embodiments among the embodiments are combined.

In an embodiment, each pixel PXL may be configured as an active pixel. However, the kind, structure, and/or driving method of pixels PXL which can be applied to the display device of the disclosure are not particularly limited. For example, each pixel PXL may be configured as a pixel of a passive or active light emitting display device using various structures and/or driving methods.

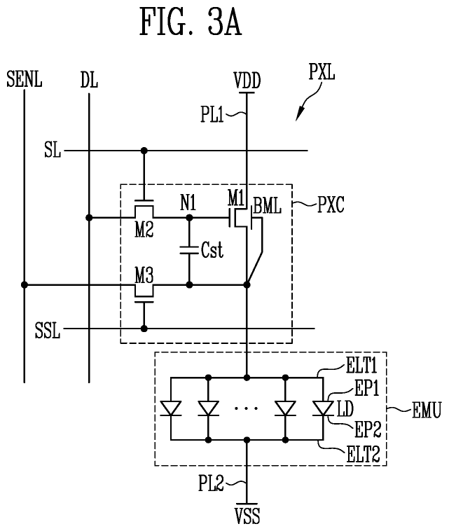

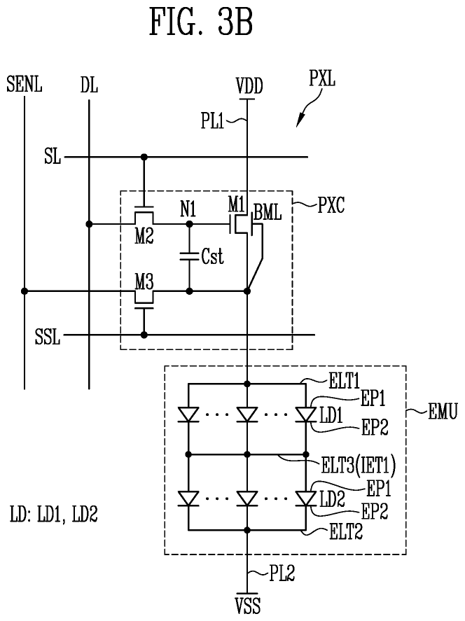

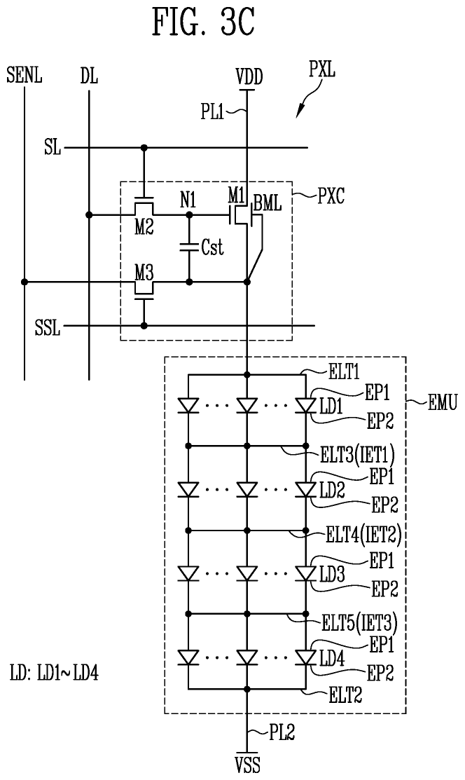

FIGS. 3A to 3C are schematic circuit diagrams illustrating a pixel included in the display device shown in FIG. 2. For example, FIGS. 3A to 3C illustrate embodiments of a pixel PXL which can be applied to an active display device, and illustrate different embodiments in relation to a structure of a light emitting unit EMU.

In some embodiments, each of pixels PXL shown in FIGS. 3A to 3C may be any of the pixels PXL disposed in the display area DA shown in FIG. 2. The pixels PXL disposed in the display area DA may have structures substantially identical or similar to each other.

Referring to FIGS. 3A to 3C, the pixel PXL may include a light emitting unit EMU for generating light with a luminance corresponding to a data signal. The pixel PXL may selectively further include a pixel circuit PXC for driving the light emitting unit EMU.

The pixel circuit PXC may be electrically connected between a first power source VDD and the light emitting unit EMU. The pixel circuit PXC may be electrically connected to a scan line SL and a data line DL of the corresponding pixel PXL, to control an operation of the light emitting unit EMU, corresponding to a scan signal and a data signal, which may be respectively supplied from the scan line SL and the data line DL. The pixel circuit PXC may be selectively further connected to a sensing signal line SSL and a sensing line SENL.

The pixel circuit PXC may include at least one transistor and a capacitor. For example, the pixel circuit PXC may include a first transistor M1, a second transistor M2, a third transistor M3, and a storage capacitor Cst.

The first transistor M1 may be electrically connected between the first power source VDD and a first pixel electrode ELT1. A gate electrode of the first transistor M1 may be electrically connected to a first node N1. The first transistor M1 may control a driving current supplied to the light emitting unit EMU, corresponding to a voltage of the first node N1. For example, the first transistor M1 may be a driving transistor for controlling the driving current of the pixel PXL.

In an embodiment, the first transistor M1 may selectively include a lower metal layer BML (also referred to as a “lower electrode,” a “back gate electrode,” or a “lower light blocking layer”). The gate electrode and the lower metal layer BML of the first transistor M1 may overlap each other with an insulating layer interposed therebetween. In an embodiment, the lower metal layer BML may be electrically connected to an electrode, e.g., a source or drain electrode of the first transistor M1.

In case that the first transistor M1 includes the lower metal layer BML, there may be applied a back-biasing technique (or sync technique) for moving a threshold voltage of the first transistor M1 in a negative direction or positive direction by applying a back-biasing voltage to the lower metal layer BML of the first transistor M1 in driving of the pixel PXL. In an example, a source-sync technique may be applied by connecting the lower metal layer BML to a source electrode of the first transistor M1, so that the threshold voltage of the first transistor M1 can be moved in the negative direction or positive direction. In case that the lower metal layer BML is disposed under a semiconductor pattern constituting a channel of the first transistor M1, the lower metal layer BML serves as a light blocking pattern, thereby stabilizing operational characteristics of the first transistor M1. However, the function and/or application method of the lower metal layer BML is not limited thereto.

The second transistor M2 may be electrically connected between the data line DL and the first node N1. A gate electrode of the second transistor M2 may be electrically connected to the scan line SL. The second transistor M2 may be turned on in case that a scan signal having a gate-on voltage (e.g., a high level voltage) is supplied from the scan line SL, to electrically connect the data line DL and the first node N1 to each other.

A data signal of a corresponding frame may be supplied to the data line DL for each frame period. The data signal may be transferred to the first node N1 through the turned-on second transistor M2 during a period in which the scan signal having the gate-on voltage may be supplied. For example, the second transistor M2 may be a switching transistor for transferring each data signal to the inside of the pixel PXL.

An electrode of the storage capacitor Cst may be electrically connected to the first node N1, and the other electrode of the storage capacitor Cst may be electrically connected to a second electrode of the first transistor M1. The storage capacitor Cst may charge a voltage corresponding to the data signal supplied to the first node N1 during each frame period.

The third transistor M3 may be electrically connected between the first pixel electrode ELT1 (or the second electrode of the first transistor M1) and the sensing line SENL. A gate electrode of the third transistor M3 may be electrically connected to the sensing signal line SSL. The third transistor M3 may transfer a voltage value applied to the first pixel electrode ELT1 to the sensing line SENL according to a sensing signal supplied to the sensing signal line SSL. The voltage value transferred through the sensing line SENL may be provided to an external circuit (e.g., a timing controller), and the external circuit may extract characteristic information (e.g., the threshold voltage of the first transistor M1, etc.), based on the provided voltage value. The extracted characteristic information may be used to convert image data such that a characteristic deviation between the pixels PXL may be compensated.

Although a case where the transistors included in the pixel circuit PXC may all implemented with an N-type transistor has been illustrated in FIGS. 3A to 3C, the disclosure is not limited thereto. For example, at least one of the first, second, and third transistors M1, M2, and M3 may be changed to a P-type transistor.

The structure and driving method of the pixel PXL may be variously changed. For example, the pixel circuit PXC may be configured as a pixel circuit having various structures and/or various driving methods, in addition to the embodiment shown in FIGS. 3A to 3C.

In an example, the pixel circuit PXC may not include the third transistor M3. The pixel circuit PXC may further include other circuit elements such as a compensation transistor for compensating for the threshold voltage of the first transistor M1, etc., an initialization transistor for initializing a voltage of the first node N1 and/or the first pixel electrode ELT1, an emission control transistor for controlling a period in which a driving current may be supplied to the light emitting unit EMU, and/or a boosting capacitor for boosting the voltage of the first node N1.

In another embodiment, in case that the pixel PXL is a pixel of a passive light emitting display device, the pixel circuit PXC may be omitted. The light emitting unit EMU may be directly connected to the scan line SL, the data line DL, a first power line PL1, a second power line PL2, and/or another signal line or power line.

The light emitting unit EMU may include at least one light emitting element LD, e.g., light emitting elements LD electrically connected between the first power source VDD and a second power source VSS.

For example, the light emitting unit EMU may include the first pixel electrode ELT1 (also referred to as a “first electrode” or a “first contact electrode”) electrically connected to the first power source VDD through the pixel circuit PXC and the first power line PL1, a second pixel electrode ELT2 (also referred to as a “second electrode” or a “second contact electrode”) electrically connected to the second power source VSS through the second power line PL2, and light emitting elements LD electrically connected between the first and second pixel electrodes ELT1 and ELT2.

The first power source VDD and the second power source VSS may have different potentials such that the light emitting elements LD can emit light. In an example, the first power source VDD may be set as a high-potential power source, and the second power source VSS may be set as a low-potential power source.

In an embodiment, the light emitting unit EMU may include light emitting elements LD connected in parallel to each other in the same direction between the first pixel electrode ELT1 and the second pixel electrode ELT2 as illustrated in the embodiment shown in FIG. 3A. For example, each light emitting element LD may include a first end portion EP1 (e.g., a P-type end portion) electrically connected to the first power source VDD through the first pixel electrode ELT1 and/or the pixel circuit PXC, and a second end portion (e.g., an N-type end portion) electrically connected to the second power source VSS through the second pixel electrode ELT2. For example, the light emitting elements LD may be connected in parallel in a forward direction between the first and second pixel electrodes ELT1 and ELT2.

The light emitting elements LD connected in the forward direction between the first power source VDD and the second power source VSS may constitute effective light sources, respectively. These effective light sources may constitute the light emitting unit EMU of the pixel PXL.

First end portions EP1 of the light emitting elements LD may be commonly connected to the pixel circuit PXC through an electrode (e.g., the first pixel electrode ELT1) of the light emitting unit EMU, and be electrically connected to the first power source VDD through the pixel circuit PXC and the first power line PL1. Second end portions EP2 of the light emitting elements LD may be commonly connected to the second power source VSS through another electrode (e.g., the second pixel electrode ELT2) of the light emitting unit EMU and the second power line PL2.

Although an embodiment in which the pixel PXL includes the light emitting unit EMU having a parallel structure is illustrated in FIG. 3A, the disclosure is not limited thereto. For example, the pixel PXL may include the light emitting unit EMU having a serial structure or a series/parallel structure. In an example, the light emitting unit EMU may include light emitting element LD dividedly connected to serial stages as illustrated in the embodiments shown in FIGS. 3B and 3C.

Referring to FIG. 3B, the light emitting unit EMU may include a first serial stage including at least one first light emitting element LD1 and a second serial stage including at least one second light emitting element LD2.

The first serial stage may include the first pixel electrode ELT1, a third pixel electrode ELT3 (also referred to as a “third electrode” or a “third contact electrode”), and at least one first light emitting element LD1 electrically connected between the first and third pixel electrodes ELT1 and ELT3. Each first light emitting element LD1 may be connected in the forward direction between the first and third pixel electrodes ELT1 and ELT3. For example, a first end portion EP1 of the first light emitting element LD1 may be electrically connected to the first pixel electrode ELT1, and a second end portion EP2 of the first light emitting element LD1 may be electrically connected to the third pixel electrode ELT3. The third pixel electrode ELT3 may constitute a first intermediate electrode IET1 which connects the first serial stage and the second serial stage to each other.

The second serial stage may include the third pixel electrode ELT3, the second pixel electrode ELT2, and at least one second light emitting element LD2 electrically connected between the second and third pixel electrodes ELT2 and ELT3. Each second light emitting element LD2 may be connected in the forward direction between the second and third pixel electrodes ELT2 and ELT3. For example, a first end portion EP1 of the second light emitting element LD2 may be electrically connected to the third pixel electrode ELT3, and a second end portion EP2 of the second light emitting element LD2 may by electrically connected to the second pixel electrode ELT2.

The number of serial stages constituting each light emitting unit EMU may be variously changed in accordance with embodiments. For example, the light emitting unit EMU may include light emitting elements LD dividedly connected to four serial stages as illustrated in the embodiment shown in FIG. 3C.

Referring to FIG. 3C, the light emitting unit EMU may include a first serial stage including at least one first light emitting element LD1, a second serial stage including at least one second light emitting element LD2, a third serial stage including at least one third light emitting element LD3, and a fourth serial stage including at least one fourth light emitting element LD4.

The first serial stage may include the first pixel electrode ELT1, the third pixel electrode ELT3, and at least one first light emitting element LD1 electrically connected between the first and third pixel electrodes ELT1 and ELT3. Each first light emitting element LD1 may be connected in the forward direction between the first and third pixel electrodes ELT1 and ELT3. For example, a first end portion EP1 of the first light emitting element LD1 may be electrically connected to the first pixel electrode ELT1, and a second end portion EP2 of the first light emitting element LD1 may be electrically connected to the third pixel electrode ELT3.

The second serial stage may include the third pixel electrode ELT3, a fourth pixel electrode (also referred to as a “fourth electrode” or a “fourth contact electrode”), and at least one second light emitting element LD2 electrically connected between the third and fourth pixel electrodes ELT3 and ELT4. Each second light emitting element LD2 may be connected in the forward direction between the third and fourth pixel electrodes ELT3 and ELT4. For example, a first end portion EP1 of the second light emitting element LD2 may be electrically connected to the third pixel electrode ELT3, and a second end portion EP2 of the second light emitting element LD2 may be electrically connected to the fourth pixel electrode ELT4.

The third serial stage may include the fourth pixel electrode, a fifth pixel electrode (also referred to as a “fifth electrode” or a “fifth contact electrode”), and at least one third light emitting element LD3 electrically connected between the fourth and fifth pixel electrodes ELT4 and ELT5. Each third light emitting element LD3 may be connected in the forward direction between the fourth and fifth pixel electrodes ELT4 and ELT5. For example, a first end portion EP1 of the third light emitting element LD3 may be electrically connected to the fourth pixel electrode ELT4, and a second end portion EP2 of the third light emitting element LD3 may be electrically connected to the fifth pixel electrode ELT5.

The fourth serial stage may include the fifth pixel electrode, the second pixel electrode ELT2, and at least one fourth light emitting element LD4 electrically connected between the second and fifth pixel electrodes ELT2 and ELT5. Each fourth light emitting element LD4 may be connected in the forward direction between the second and fifth pixel electrodes ELT2 and ELT5. For example, a first end portion EP1 of the fourth light emitting element LD4 may be electrically connected to the fifth pixel electrode ELT5, and a second end portion EP2 of the fourth light emitting element LD4 may be electrically connected to the second pixel electrode ELT2.

In the embodiments shown in FIGS. 3A to 3C, the light emitting unit EMU may include at least one serial stage. Each serial stage may include a pair of pixel electrodes (e.g., two pixel electrodes) and at least one light emitting element LD connected in the forward direction between the pair of pixel electrodes. The number of serial stages constituting the light emitting unit EMU and the number of light emitting elements LD constituting each serial stage are not particularly limited. In an example, numbers of light emitting elements LD constituting respective serial stages may be equal to or different from each other, and the number of the light emitting elements LD is not particularly limited.

A first electrode, e.g., the first pixel electrode ELT1 of the light emitting unit EMU may be an anode electrode of the light emitting unit EMU. A last electrode, e.g., the second pixel electrode ELT2 of the light emitting unit EMU may be a cathode electrode of the light emitting element EMU.

The other electrodes of the light emitting unit EMU, e.g., the third pixel electrode ELT3, the fourth pixel electrode ELT4, and/or the fifth pixel electrode ELT5, which are shown in FIGS. 3B and 3C, may constitute intermediate electrodes, respectively. For example, the third pixel electrode ELT3 may constitute the first intermediate electrode IET1, the fourth pixel electrode ELT4 may constitute a second intermediate electrode IET2, and the fifth pixel electrode ELT5 may constitute a third intermediate electrode IET3.

In case that light emitting elements LD are connected only in parallel as illustrated in the embodiment shown in FIG. 3A, the structure of the pixel PXL can be simplified. In case that light emitting elements LD are connected in a series structure or a series/parallel structure as illustrated in the embodiments shown in FIGS. 3B and 3C, power efficiency can be improved as compared with an embodiment (e.g., the embodiment shown in FIG. 3A) in which the same number of light emitting elements LD are connected only in parallel. In the pixel PXL in which the light emitting elements LD are connected in the series structure or the series/parallel structure, a luminance can be expressed through light emitting elements LD of the other serial stage. Hence, the probability that a dark spot failure will occur in the pixel PXL can be reduced.

Although embodiments in which light emitting elements LD are connected in a parallel structure or a series/parallel structure have been illustrated in FIGS. 3A to 3C, the disclosure is not limited thereto. For example, in another embodiment, the light emitting unit EMU may be configured by connecting light emitting elements LD only in series.

Each of the light emitting elements LD may include a first end portion EP1 (e.g., a P-type end portion) connected to the first power source VDD via at least one pixel electrode (e.g., the first pixel electrode EL1), the pixel circuit PXC, and/or the first power line PL1, and a second end portion EP2 (e.g., an N-type end portion) connected to the second power source VSS via at least another electrode (e.g., the second pixel electrode ELT2) and the second power line PL2. For example, the light emitting elements LD may be connected in the forward direction between the first power source VDD and the second power source VSS. The light emitting elements LD connected in the forward direction may constitute effective light sources of the light emitting unit EMU.

In case that a driving current is supplied through the corresponding pixel circuit PXC, the light emitting elements LD may emit light with a luminance corresponding to the driving current. For example, during each frame period, the pixel circuit PXC may supply, to the light emitting unit EMU, a driving current corresponding to a grayscale value to be expressed in a corresponding frame. Accordingly, while the light emitting elements LD may emit light with the luminance corresponding to the driving current, the light emitting unit EMU can express the luminance corresponding to the driving current.

In an embodiment, the light emitting unit EMU may further include at least one non-effective light source in addition to the light emitting elements LD constituting the respective effective light sources. In an example, at least one non-effective light emitting element which may be arranged in a reverse direction or has at least one floated end portion may be further connected to at least one serial stage. The non-effective light emitting element maintains an inactivated state even in case that a driving voltage is applied in the forward direction between pixel electrodes. Accordingly, the non-effective light emitting element can maintain a substantially non-emission state.

FIG. 4 is a schematic plan view illustrating an embodiment of the pixel included in the display device shown in FIG. 2. For example, FIG. 4 illustrates an embodiment of a pixel area PXA of a pixel PXL, based on a light emitting unit EMU of the pixel PXL, which includes four serial stages as illustrated in the embodiment shown in FIG. 3C.

Referring to FIGS. 2, 3C, and 4, the pixel PXL may include an emission area EA, a non-emission area NEA, and a separation area SPA. For example, a pixel area PXA in which each pixel PXL may be provided may include an emission area EA in which light emitting elements LD may be provided and/or aligned, a non-emission area NEA surrounding the emission area EA, and a separation area SPA spaced apart from the emission area EA with the non-emission area NEA interposed therebetween.

The emission area may be an area which includes light emitting elements LD, to emit light. The non-emission area NEA may be an area in which a bank BNK surrounding the emission area EA may be provided. The emission area EA may be located in a first opening OPA1 of the bank BNK. The separation area SPA may be an area which may be located in a second opening OPA2 of the bank BNK in the other pixel area PXA except the emission area EA, and has at least one alignment electrode ALE cut therein.

The pixel PXL may include pixel electrodes ELT provided in at least the emission area EA, light emitting elements LD electrically connected between the pixel electrodes ELT, alignment electrodes ALE provided at positions corresponding to the pixel electrodes ELT, and patterns BNP (or bank patterns) provided under the alignment electrodes ALE to each overlap at least one alignment electrode ALE. For example, the pixel PXL may include first to fifth pixel electrodes ELT1 to ELT5 provided in at least the emission area EA, first to fourth light emitting elements LD1 to LD4 electrically connected between the first to fifth pixel electrodes ELT1 to ELT5, first to fourth alignment electrodes ALE1 to ALE4 provided under the first to fifth pixel electrodes ELT1 to ELT5 to each overlap at least one pixel electrode ELT, and first to third patterns BNP1 to BNP3 provided under the first to fourth alignment electrodes ALE1 to ALE4 to each partially overlap at least one alignment electrode ALE. The pixel PXL may further include a first connection electrode ALE5 (or fifth alignment electrode) electrically connecting the first pixel electrode ELT1 to the pixel circuit PXC (see FIG. 3C), and a second connection electrode ALE6 (or sixth alignment electrode) electrically connecting the second pixel electrode ELT2 to the second power line PL2 (see FIG. 3C). The first and second connection electrodes ALE5 and ALE6 may include the same material as the alignment electrodes ALE through the same process as the alignment electrodes ALE. In some embodiments, the first connection electrode ALE5 may be integrally formed with the first alignment electrode ALE1 and be a portion of the first alignment electrode ALE1. Similarly, the second connection electrode ALE6 may be integrally formed with the second alignment electrode ALE2 and be a portion of the second alignment electrode ALE2.

The pixel may include at least one pair of pixel electrodes ELT, at least one pair of alignment electrodes ALE, and/or at least one pair of patterns BNP, and the number, shape, size, and arrangement structure of each of the pixel electrodes ELT, the alignment electrodes ALE, and/or the patterns BNP may be variously changed according to the structure of the pixel PXL (particularly, the light emitting unit EMU described with reference to FIGS. 3A to 3C).

In an embodiment, the patterns BNP, the alignment electrodes ALE, the light emitting elements LD, and the pixel electrodes ELT may be sequentially provided with respect to a surface of the base layer BSL (see FIG. 2), on which the pixel PXL may be formed. In another embodiment, the alignment electrodes ALE, the patterns BNP, the light emitting elements LD, and the pixel electrodes ELT may be sequentially provided with respect to the surface of the base layer BSL (see FIG. 2), on which the pixel PXL may be formed. The positions and forming order of electrode patterns and/or insulating patterns, which constitute the pixel PXL may be variously changed in accordance with embodiments. A sectional structure of the pixel PXL will be described in detail later.

The patterns BNP may be provided in at least the emission area EA. The patterns BNP may be spaced apart from each other along a first direction DR1 in the emission area EA, and each of the patterns BNP may extend along a second direction DR2. In an embodiment, the first direction DR1 may be a lateral direction or row direction, and the second direction DR2 may be a longitudinal direction or column direction. However, the disclosure is not limited thereto.

Each pattern BNP (also referred to as a “wall pattern” or a “protrusion pattern”) may have a uniform width in the emission area EA. In an example, each of the first, second, and third patterns BNP1, BNP2, and BNP3 may have a linear pattern shape having a constant width in the emission area EA in a plan view.

The patterns BNP may have widths equal to or different from each other. For example, the first and third patterns BNP1 and BNP3 may have the same width in at least the emission area EA, and face each other with the second pattern BNP2 interposed therebetween. In an example, the first and third patterns BNP1 and BNP3 may be formed symmetrically to each other with respect to the second pattern BNP2 in the emission area EA.

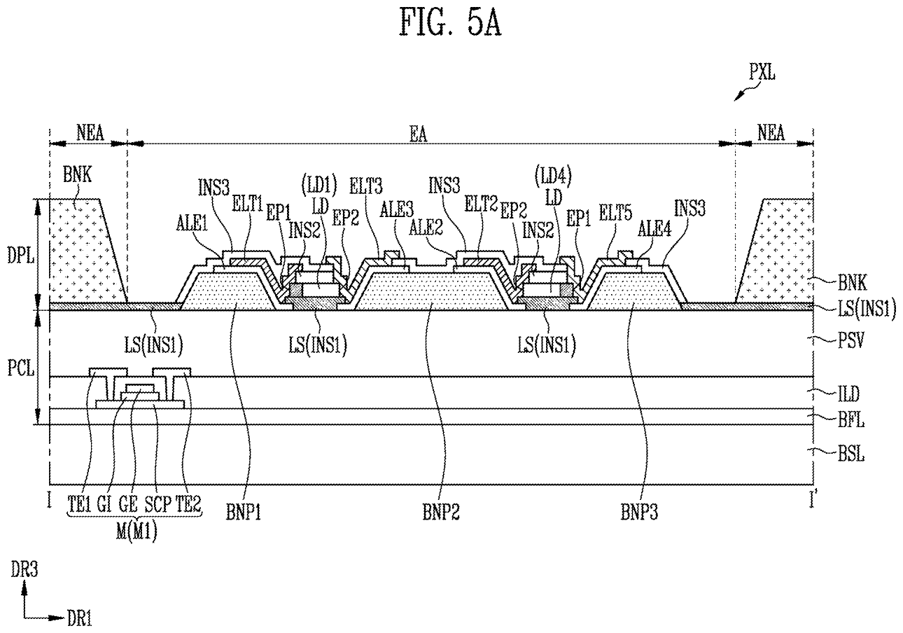

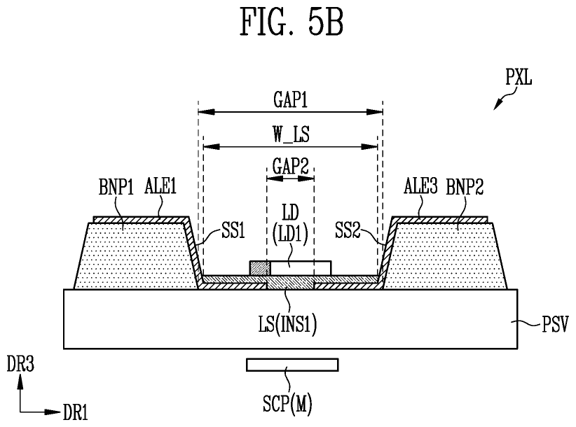

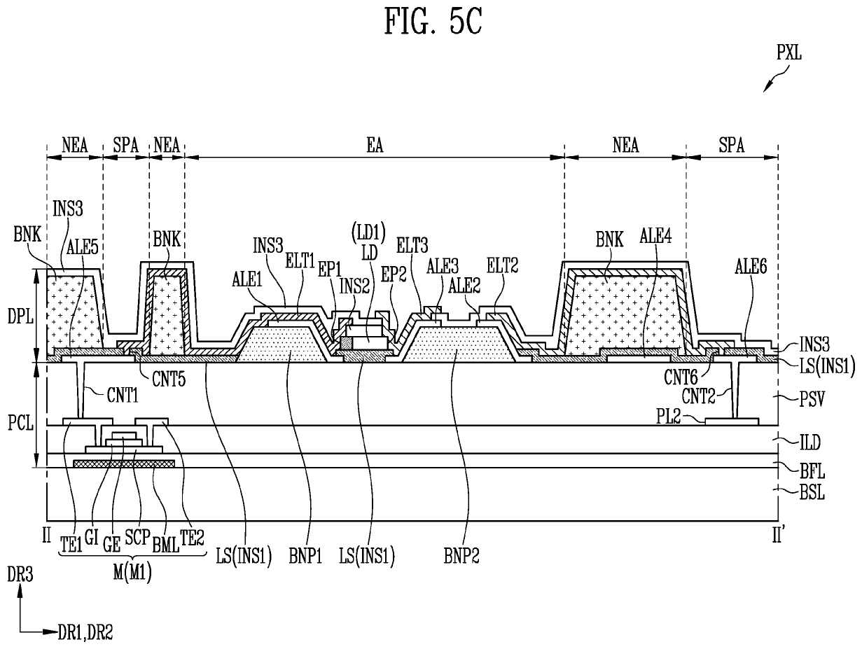

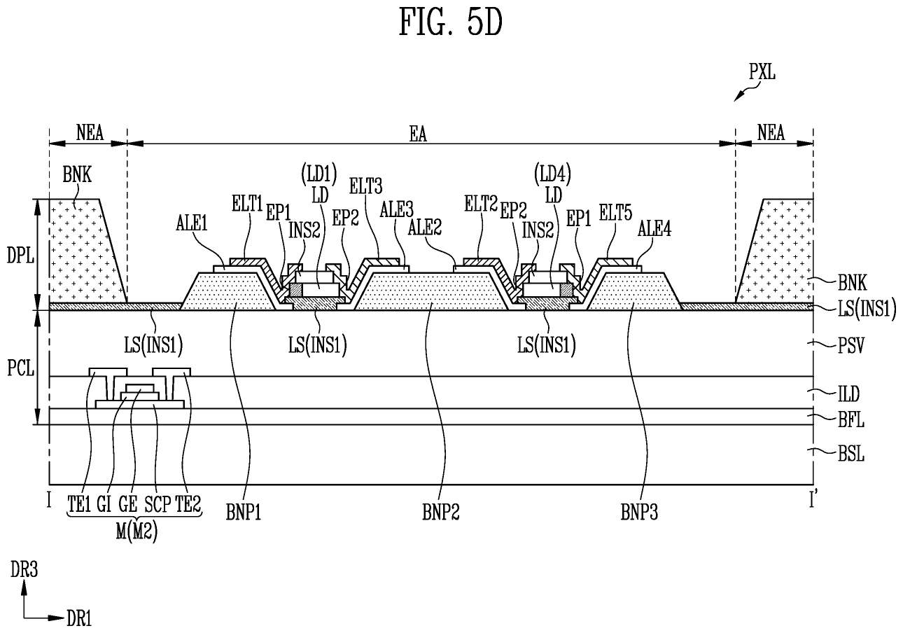

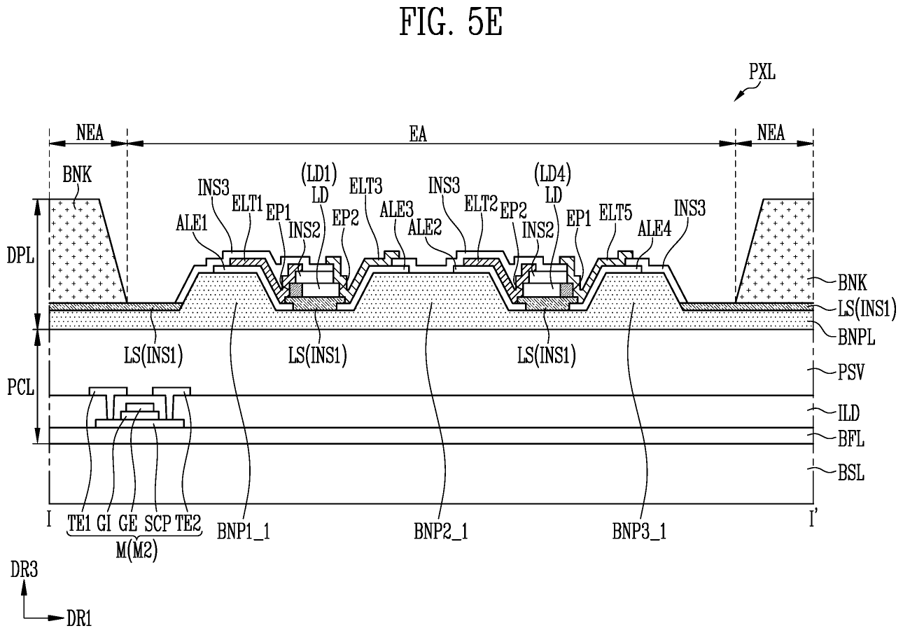

The patterns BNP may be arranged at a uniform distance in the emission area EA. For example, the first, second, and third patterns BNP1, BNP2, and BNP3 may be sequentially arranged at a constant distance corresponding to a first distance GAP1 (see FIG. 5B) along the first direction DR1 in the emission area EA.

Each pattern BNP may partially overlap at least one alignment electrode ALE in at least the emission area EA. For example, the first pattern BNP1 may be provided under the first alignment electrode ALE1 to overlap an area of the first alignment electrode ALE1, the second pattern BNP2 may be provided under the second and third alignment electrodes ALE2 and ALE3 to overlap an area of the second and third alignment electrodes ALE2 and ALE3, and the third pattern BNP3 may be provided under the fourth alignment electrode ALE4 to overlap an area of the fourth alignment electrode ALE4.

In case that the patterns BNP are provided under an area of each of the alignment electrodes ALE, the area of each of the alignment electrodes ALE may protrude in an upper direction of the pixel PXL in an area in which the patterns PNP are formed. Accordingly, a wall structure may be formed at the periphery of the light emitting elements LD. For example, the wall structure may be formed in the emission area EA to face first and second end portions of the light emitting elements LD.

In an embodiment, in case that the patterns BNP and/or the alignment electrodes ALE include a reflective material, a reflective wall structure may be formed at the periphery of the light emitting elements LD. Accordingly, light emitted from the light emitting elements LD may be further oriented in the upper direction of the pixel PXL (e.g., a front direction of the display panel PNL, which includes a viewing angle range), thereby improving the light efficiency of the pixel PXL.

In an embodiment, at least one pattern BNP may extend from the emission area EA to the non-emission area NEA. The at least one pattern BNP may overlap an edge area of the bank BNK at a boundary between the non-emission area NEA and the separation area SPA, e.g., a lower end edge area and/or an upper end edge area with respect to the emission area EA. For example, the second pattern BNP2 may have a shape vertically symmetrical with respect to the emission area EA. However, the disclosure is not limited thereto. For example, in another embodiment, the second pattern BNP2 may extend even to the separation area SPA. Similarly to the second pattern BNP2, the first pattern BNP1 and the third pattern BNP3 may extend from the emission area EA to the non-emission area NEA. In a manufacturing process of the pixel PXL, an electric field (and an electric-osmosis or alternating current electric-osmosis (ACEO) phenomenon according to the electric field) may be uniformly generated between the first, second, third, and fourth alignment electrodes ALE1, ALE2, ALE3, and ALE4 disposed on the first to third patterns BNP1, BNP2, and BNP3 in the emission area EA. In particular, the electric field may be uniformly generated even at an edge of the emission area EA, which may be adjacent to the non-emission area NEA, and the light emitting elements LD may be more uniformly aligned between the first, second, third, and fourth alignment electrodes ALE1, ALE2, ALE3, and ALE4.

The alignment electrodes ALE may be provided in at least the emission area EA. The alignment electrodes ALE may be spaced apart from each other along the first direction DR1 in the emission area EA, and each of the alignment electrodes ALE may extend along the second direction DR2. The alignment electrodes ALE may extend to the separation area SPA via the non-emission area NEA from the emission area EA, and be cut in the separation area SPA. For example, each of the first to fourth alignment electrodes ALE1 to ALE4 may extend from the emission area EA to the separation area SPA and be cut in the separation area SPA (or a removal area RA in the separation area SPA), to be separated from alignment electrodes ALE of an adjacent pixel PXL. In another embodiment, at least one of the alignment electrodes ALE, e.g., the second alignment electrode ALE2 may not be cut in the separation area SPA but may be integrally connected to a second alignment electrode ALE2 of an adjacent pixel PXL.

The first and second connection electrodes ALE5 and ALE6 may be provided in at least the separation area SPA, and be disposed to be spaced part from the alignment electrodes ALE. For example, the first connection electrode ALE5 may extend from a left side point of the first alignment electrode ALE1 to the non-emission area NEA. The second connection electrode ALE6 may be disposed at a right side of the fourth alignment electrode ALE4.

The first and second connection electrodes ALE5 and ALE6 may be electrically connected to the pixel circuit PXC and/or a power line through respective contact parts (or contact holes). For example, the first connection electrode ALE5 may be electrically connected to the pixel circuit PXC (see FIG. 3C) and/or the first power line PL1 (see FIG. 3C) through a first contact part CNT1, and the second connection electrode ALE6 may be electrically connected to the second power line PL2 (see FIG. 3C) through a second contact part CNT2. The first and second contact parts CNT1 and CNT2 may be formed in at least one insulating layer (e.g., a passivation layer PSV shown in FIG. 5B) covering the pixel circuit PXC (see FIG. 3C).

The first and second contact parts CNT1 and CNT2 may be formed in the separation area SPA or the non-emission area NEA. For example, the first contact part CNT1 may be formed in the non-emission area NEA, and the second contact part CNT2 may be formed in the separation area. The positions of the first and second contact parts CNT1 and CNT2 are not limited thereto, and may be variously changed corresponding to the arrangement of the pixel circuit PXC (or the first transistor M1 (see FIG. 3C), the first power line PL1, and the second power line PL2. The shapes of the first and second connection electrodes ALE5 and ALE6 may be variously changed according to the positions of the first and second contact parts CNT1 and CNT2.

In some embodiments, the first and second connection electrodes ALE5 and ALE6 may be connected to a pixel electrode ELT through a contact part. For example, the first connection electrode ALE5 may be connected to the first pixel electrode ELT1 through a fifth contact part CNT5 (or first contact hole), and the second connection electrode ALE6 may be connected to the second pixel electrode ELT2 through a sixth contact part CNT6 (or second contact hole). The fifth contact part CNT5 and the sixth contact part CNT6 may be provided in the separation area SPA. For example, the fifth contact part CNT5 and the sixth contact part CNT6 may be formed in at least one insulating layer (e.g., a light blocking pattern LS or a first insulating layer INS1, which is shown in FIG. 5C) covering the first and second connection electrodes ALE5 and ALE6 (and the alignment electrodes ALE).

At least some of the alignment electrodes ALE may be connected to the pixel circuit PXC and/or a power line through contact parts. For example, the first alignment electrode ALE1 may be connected to the first power line PL1 (see FIG. 3C) through a third contact part CNT3, and the fourth alignment electrode ALE4 may be connected to the first power line PL1 through a fourth contact part CNT4. The second alignment electrode ALE2 and the third alignment electrode ALE3 may be connected to the second power line PL2 (see FIG. 3C) through a dummy alignment electrode ALE_D and a dummy contact part CNT_D. For example, each of the first to fourth alignment electrodes ALE1 to ALE4 may be cut in the separation area SPA (or the removal area RA in the separation area SPA), to be separated from the first and second power lines PL1 and PL2.

Each alignment electrode ALE may be located on a pattern BNP. For example, the first alignment electrode ALE1 may be located on an area of the first pattern BNP1, the second and third alignment electrodes ALE2 and ALE3 may be located on different areas of the second pattern BNP2, and the fourth alignment electrode ALE4 may be located on an area of the third pattern BNP3. In an embodiment, in case that the third alignment electrode ALE3 is located between the first and second alignment electrodes ALE1 and ALE2, the third alignment electrode ALE3 may be located on a left area of the second pattern BNP2, and the second alignment electrode ALE2 may be located on a right area of the second pattern BNP2. Although a case where the first alignment electrode ALE1 partially overlaps the first pattern BNP1 and the fourth alignment electrode ALE4 partially overlap the second pattern BNP2 is illustrated in FIG. 4, the disclosure is not limited thereto. For example, the first alignment electrode ALE1 may be disposed to cover the first pattern BNP1, and the fourth alignment electrode ALE4 may be disposed to cover the second pattern BNP2.

Each alignment electrode ALE may have a uniform width in the emission area EA. In an example, each of the first, second, third, and fourth electrodes ALE1, ALE2, ALE3, and ALE4 may have a linear pattern shape having a constant width in the emission area EA in a plan view. The alignment electrodes ALE may have widths equal to or different from each other.

Each alignment electrode ALE may be continuously formed along the second direction DR2 in the emission area EA. For example, each alignment electrode ALE may extend along the second direction DR2 not to be cut in the emission area EA.

A pair of alignment electrodes ALE adjacent to each other may be supplied with different signals in a process of aligning the light emitting elements LD, and be spaced apart from each other at a uniform distance in the emission area EA. When assuming that at least two pairs of alignment electrodes ALE are provided in the emission area EA, each pair of alignment electrodes ALE may be spaced apart from each other at the same distance.

For example, it will be assumed that the first alignment electrode ALE1, the third alignment electrode ALE3, the second alignment electrode ALE2, and the fourth alignment electrode ALE4 are sequentially arranged along the first direction DR1 in the emission area EA, the first and third alignment electrodes ALE1 and ALE3 form a pair to be supplied with different alignment signals, and the second and fourth alignment electrode ALE2 and ALE4 form a pair to be supplied with different alignment signals. In the emission area EA, the first and third alignment electrodes ALE1 and ALE3 may be spaced part from each other at a constant distance corresponding to a second distance GAP2 (see FIG. 5B) along the first direction DR1, and the second and fourth alignment electrodes ALE2 and ALE4 may also be spaced apart from each other at a constant distance corresponding to the second distance GAP2 along the first direction DR1.

In an embodiment, the second and third alignment electrodes ALE2 and ALE3 may be supplied with the same signal in the process of aligning the light emitting elements LD during the process of manufacturing the pixel PXL. The second and third alignment electrodes ALE2 and ALE3 may be spaced apart from each other at a distance equal to or different from the second distance. The second and third alignment electrodes ALE2 and ALE3 may be integrally or non-integrally connected to each other in the process of aligning the light emitting elements LD.

Each alignment electrode ALE may have or may not have a bending part in the non-emission area NEA and/or the separation area SPA, and the shape and/or size of each alignment electrode ALE in an area except the emission area EA. For example, the shapes and/or sizes of the alignment electrodes ALE may be variously changed in the non-emission area NEA and/or the separation area SPA.

Each of the light emitting elements LD may be aligned between a pair of patterns BNP, and be connected between a pair of pixel electrodes ELT.

For example, each first light emitting element LD1 may be aligned between the first and second patterns BNP1 and BNP2 to be electrically connected between the first and third pixel electrodes ELT1 and ELT3, and each second light emitting element LD2 may be aligned between the first and second patterns BNP1 and BNP2 to be electrically connected between the third and fourth pixel electrodes ELT3 and ELT4. In an example, each first light emitting element LD1 may be aligned in a lower end area in an area between the first and second patterns BNP1 and BNP2, and a first end portion EP1 and a second end portion EP2 of the first light emitting element LD1 may be respectively connected to the first pixel electrode ELT1 and the third pixel electrode ELT3. Each second light emitting element LD2 may be aligned in an upper end area in the area between the first and second patterns BNP1 and BNP2, and a first end portion EP1 and a second end portion EP2 of the second light emitting element LD2 may be respectively connected to the third pixel electrode ELT3 and the fourth pixel electrode ELT4.

Similarly, each third light emitting element LD3 may be aligned between the second and third patterns BNP2 and BNP3 to be electrically connected between the fourth and fifth pixel electrodes ELT4 and ELT5, and each fourth light emitting element LD4 may be aligned between the second and third patterns BNP2 and BNP3 to be electrically connected between the second and fifth pixel electrodes ELT2 and ELT5. In an example, each third light emitting element LD3 may be aligned in an upper end area in an area between the second and third patterns BNP2 and BNP3, and a first end portion EP1 and a second end portion EP2 of the third light emitting element LD3 may be respectively connected to the fourth pixel electrode ELT4 and the fifth pixel electrode ELT5. Each fourth light emitting element LD4 may be aligned in a lower end area in the area between the second and third patterns BNP2 and BNP3, and a first end portion EP1 and a second end portion EP2 of the fourth light emitting element LD4 may be respectively connected to the fifth pixel electrode ELT5 and the second pixel electrode ELT2.

In an example, the first light emitting elements LD1 may be located in a left lower end area of the emission area EA, and the second light emitting elements LD2 may be located in a left upper end area of the emission area EA. The third light emitting elements LD3 may be located in a right upper end area of the emission area EA, and the fourth light emitting elements LD4 may be located in a right lower end area of the emission area EA. However, the arrangement and/or connection structure of the light emitting elements LD may be variously changed according to the structure of the light emitting unit EMU and/or the number of serial stages.

The pixel electrodes ELT may be provided in at least the emission area EA, and each be provided at a position corresponding to at least one alignment electrode ALE and at least one light emitting element LD. For example, each pixel electrode ELT may be formed on each alignment electrode ALE and each light emitting element LD to overlap the alignment electrode ALE and the light emitting element LD. Therefore, each pixel electrode ELT may be electrically connected to at least the light emitting element LD. In an example, each pixel electrode ELT may be connected to an end portion of at least one light emitting element LD in the emission area.

The first pixel electrode ELT1 may be formed on a first area (e.g., a lower end area) of the first alignment electrode ALE1 and first end portions EP1 of the first light emitting elements LD1, to be electrically connected to the first end portions EP1 of the first light emitting elements LD1. For example, the first pixel electrode ELT1 may be connected to the first end portions EP1 of the first light emitting elements LD1 in the emission area EA.

The second pixel electrode ELT2 may be formed on a first area (e.g., a lower end area) of the second alignment electrode ALE2 and second end portions EP2 of the fourth light emitting elements LD4, to be electrically connected to the second end portions EP2 of the fourth light emitting elements LD4. For example, the second pixel electrode ELT2 may be connected to the second end portions EP2 of the fourth light emitting elements LD4 in the emission area EA.

The first pixel electrode ELT1 may be electrically connected to first end portions EP1 of the fourth light emitting elements LD4 via at least another pixel electrode ELT and/or at least another light emitting element LD. In an example, the first pixel electrode ELT1 may be connected to the first end portions EP1 of the fourth light emitting elements LD4 via the first light emitting element LD1, the third pixel electrode ELT3, the second light emitting element LD2, the fourth pixel electrode ELT4, the third light emitting element LD3, and the fifth pixel electrode ELT5.

The third pixel electrode ELT3 may be formed on a first area (e.g., a lower end area) of the third alignment electrode ALE3 and the second end portions EP2 of the first light emitting elements LD1, to be electrically connected to the second end portions EP2 of the first light emitting elements LD1. The third pixel electrode ELT3 may be formed on a second area (e.g., an upper end area) of the first alignment electrode ALE1 and first end portions EP1 of the second light emitting elements LD2, to be electrically connected to the first end portions EP1 of the second light emitting elements LD2. For example, the third pixel electrode ELT3 may be connected to the second end portions EP2 of the first light emitting elements LD1 and the first end portions EP1 of the second light emitting elements LD2 in the emission area EA.

To this end, the third pixel electrode ELT3 may have a bent shape. For example, the third pixel electrode ELT3 may have a structure in which the third pixel electrode ELT3 may be warped or curved at a boundary between an area in which at least one first light emitting element LD1 may be arranged and an area in which at least one second light emitting element LD2 may be arranged.

The third pixel electrode ELT3 may be located between the first and second pixel electrodes ELT1 and ELT2, and be electrically connected between the first and second pixel electrodes ELT1 and ELT2 through the light emitting elements LD. For example, the third pixel electrode ELT3 may be connected to the first pixel electrode ELT1 through at least one first light emitting element LD1, and be connected to the second pixel electrode ELT2 through at least one second light emitting element LD2, at least one third light emitting element LD3, and/or at least one fourth light emitting element LD4.

The fourth pixel electrode ELT4 may be formed on a second area (e.g., an upper end area) of the third alignment electrode ALE3 and second end portions EP2 of the second light emitting elements LD2, to be electrically connected to the second end portions EP2 of the second light emitting elements LD2. The fourth pixel electrode ELT4 may be formed on a second area (e.g., an upper end area) of the fourth alignment electrode ALE4 and first end portions EP1 of the third light emitting elements LD3, to be electrically connected to the first end portions EP1 of the third light emitting elements LD3. For example, the fourth pixel electrode ELT4 may be connected to the second end portions EP2 of the second light emitting elements LD2 and the first end portions EP1 of the third light emitting elements LD3 in the emission area EA.

To this end, the fourth pixel electrode ELT4 may have a bent shape. For example, the fourth pixel electrode ELT4 may have a structure in which the fourth pixel electrode ELT4 may be warped or curved at a boundary between an area in which at least one second light emitting element LD2 may be arranged and an area in which at least one third light emitting element LD3 may be arranged or at the periphery thereof. In an embodiment, the fourth pixel electrode ELT4 may not extend to the non-emission area NEA, but may be formed in only the emission area EA. However, the disclosure is not limited thereto.

The fourth pixel electrode ELT4 may be electrically connected between the first and second pixel electrodes ELT1 and ELT2 through the light emitting elements LD. For example, the fourth pixel electrode ELT4 may be connected to the first pixel electrode ELT1 through at least one first light emitting element LD1 and/or at least one second light emitting element LD2, and be connected to the second pixel electrode ELT2 through at least one third light emitting element LD3 and/or at least one fourth light emitting element LD4.

The fifth pixel electrode ELT5 may be formed on a second area (e.g., an upper end area) of the second alignment electrode ALE2 and second end portions EP2 of the third light emitting elements LD3, to be electrically connected to the second end portions EP2 of the third light emitting elements LD3. The fifth pixel electrode ELT5 may be formed on a first area (e.g., a lower end area) of the fourth alignment electrode ALE4 and first end portions EP1 of the fourth light emitting elements LD4, to be electrically connected to the first end portions EP1 of the fourth light emitting elements LD4. For example, the fifth pixel electrode ELT5 may be connected to the second end portions EP2 of the third light emitting elements LD3 and the first end portions EP1 of the fourth light emitting elements LD4 in the emission area EA.

To this end, the fifth pixel electrode ELT5 may have a bent shape. For example, the fifth pixel electrode ELT5 may have a structure in which the fifth pixel electrode ELT5 may be warped or curved at a boundary between an area in which at least one third light emitting element LD3 may be arranged and an area in which at least one fourth light emitting element LD4 may be arranged.

The fifth pixel electrode ELT5 may be electrically connected between the first and second pixel electrodes ELT1 and ELT2 through the light emitting elements LD. For example, the fifth pixel electrode ELT5 may be connected to the first pixel electrode ELT1 through at least one first light emitting element LD1, at least one second light emitting element LD2, and/or at least one third light emitting element LD3, and be connected to the second pixel electrode ELT2 through at least one fourth light emitting element LD4.

In an embodiment of the disclosure, at least one pixel electrode ELT may extend to the separation area SPA via the non-emission area NEA from the emission area EA, and each be connected to any one alignment electrode ALE through each contact part in the separation area SPA. For example, the first and second pixel electrodes ELT1 and ELT2 may extend from the emission area EA to the separation area SPA. In the separation area SPA, the first pixel electrode ELT1 may be connected to the first connection electrode ALE5 through the fifth contact part CNT5, and the second pixel electrode ELT2 may be connected to the second connection electrode ALE6 through the sixth contact part CNT6.

In the above-described manner, light emitting elements LD aligned between alignment electrodes ALE and/or patterns BNP corresponding thereto may be connected in a desired form by using the pixel electrodes ELT. For example, the first light emitting elements LD1, the second light emitting elements LD2, the third light emitting elements LD3, and the fourth light emitting elements LD4 may be sequentially connected in series by using the pixel electrodes ELT.

In order to increase the utilization of light emitting elements LD supplied to each emission area EA, the light emitting elements LD may be aligned such that a larger number (or ratio) of light emitting elements LD are aligned in a specific direction in each emission area EA by adjusting alignment signals for aligning the light emitting elements LD, by forming a magnetic field, or the like. A larger number of light emitting elements LD may be connected along a direction in which the light emitting elements LD may be aligned, by using the pixel electrodes ELT. Accordingly, the utilization of the light emitting elements LD can be increased, and the light efficiency of the pixel PXL can be improved.

In an embodiment, each pixel electrode ELT may be directly formed on first and second end portions EP1 or EP2 of adjacent light emitting elements LD, to be connected to the first and second end portions EP1 or EP2 of the light emitting elements LD.

The pixel electrodes ELT and the first and second connection electrodes ALE5 and ALE6 may be connected to each other through each contact part at the outside of the emission area EA (e.g., the separation area SPA). The contact part may be formed while avoiding the emission area EA in which the light emitting elements LD may be supplied and aligned, so that a more uniform electric field may be formed in the emission area EA in the process of aligning the light emitting elements LD. Accordingly, separation of the light emitting elements LD can be prevented.

The bank BNK may be provided in the non-emission area NEA to surround the emission area EA and the separation area SPA. The bank BNK may be provided between an outer portion of each pixel area PXA and/or adjacent pixel areas PXA to include openings OPA corresponding to emission areas EA and separation areas SPA of pixels PXL. In an example, in each pixel area PXA, the bank BNK may include a first opening OPA1 corresponding to the emission area EA and a second opening OPA2 corresponding to the separation area SPA.

The bank BNK may be a dam structure which defines each emission area EA to which light emitting elements LD are to be supplied, in a process of supplying the light emitting elements LD to each pixel PXL. For example, each emission area EA may be partitioned by the bank BNK, so that a desired amount and/or a desired kind of light emitting element ink can be supplied to the emission area EA.

The bank BNK may include at least one light blocking material and/or at least one reflective material, and accordingly, light leakage between adjacent pixels PXL can be prevented. For example, the bank BNK may include at least one black matrix material and/or at least one color filter material. In an example, the bank BNK may be formed as a black opaque pattern capable of blocking light from being transmitted therethrough. In an embodiment, a reflective layer or the like may be formed on a surface (e.g., a sidewall) of the bank BNK so as to improve the light efficiency of each pixel PXL.

The bank BNK may be formed in a layer different from that of the patterns BNP through a process separate from that of forming the patterns BNP. In an example, the bank BNK may be formed on the top of an insulating layer (e.g., the first insulating layer INS1 shown in FIGS. 5A and 5C) provided on the patterns BNP and the alignment electrodes ALE.

The bank BNK may be provided in the same layer as the patterns BNP or be provided in a layer different from that of the patterns BNP. In case that the bank BNK and the patterns BNP are sequentially formed, the positions and/or forming order of the bank BNK and the patterns BNP is not particularly limited. The bank BNK may be integrally formed with the patterns BNP or be formed separately from the patterns BNP.

In an embodiment, the patterns BNP may be first formed on a surface of the base layer BSL. Subsequently, the alignment electrodes ALE and the bank BNK may be sequentially formed on the surface of the base layer BSL, on which the patterns BNP may be formed. In another embodiment, the alignment electrodes ALE may be first formed on a surface of the base layer BSL. Subsequently, the patterns BNP and the bank BNK may be simultaneously or sequentially formed on the surface of the base layer BSL, on which the alignment electrodes ALE may be formed. In still another embodiment, the patterns BNP and the bank BNK may be first formed on a surface of the base layer BSL. Subsequently, the alignment electrodes ALE may be formed on the surface of the base layer BSL, on which the patterns BNP and the bank BNK may be formed.

In case that the patterns BNP and the bank BNK are simultaneously formed, the patterns BNP and the bank BNK may be formed to be connected to each other or not to be connected to each other. In an example, the patterns BNP and the bank BNK may be integrally formed such that lower surfaces, etc. may be connected to each other. In other embodiments, although the patterns BNP and the bank BNK may be simultaneously formed, the patterns BNP and the bank BNK may be formed not to be connected to each other. In an example, the patterns BNP and the bank BNK may be simultaneously formed in the same layer, and be separated from each other while having patterns independent from each other.

FIG. 5A is a schematic sectional view illustrating an embodiment of the pixel taken along line I-I′ shown in FIG. 4. In FIG. 5A, an arbitrary transistor M (e.g., the second transistor M2 shown in FIGS. 3A to 3C) which may not include any bottom metal layer BML is illustrated as an example of circuit elements to be disposed in a pixel layer PCL. FIG. 5B is a schematic sectional view illustrating an embodiment of the pixel shown in FIG. 5A. In FIG. 5B, the pixel PXL shown in FIG. 5A is briefly illustrated based on a light emitting element LD, first and third alignment electrodes ALE1 and ALE3, and a semiconductor pattern SCP of the transistor M. FIG. 5C is a schematic sectional view illustrating an embodiment of the pixel taken along line II-IF shown in FIG. 4. In FIG. 5C, a section of the pixel PXL including a contact part is illustrated. In FIG. 5C, a transistor M (e.g., the first transistor M1 shown in FIGS. 3A to 3C) which may be connected to a first connection electrode ALE5 through a first contact part CNT1 and includes a bottom metal layer BML is illustrated as an example of circuit elements disposed in the circuit layer PCL, and a second power line PL2 connected to a second alignment electrode ALE2 through a second contact part CNT2 is illustrated as an example, to be disposed in the circuit layer PCL. FIG. 5D is a schematic sectional view illustrating another embodiment of the pixel taken along the line I-I′ shown in FIG. 4. FIG. 5E is a schematic sectional view illustrating still another embodiment of the pixel taken along the line I-I′ shown in FIG. 4. Sections corresponding to FIG. 5A are illustrated.

First, referring to FIGS. 2, 3A to 3C, 4, 5A, 5B, and 5C, the pixel PXL and the display device DD (see FIG. 2) having the same may include a circuit layer PCL (or pixel circuit layer) and a display layer DPL (or display element layer), which are disposed on a surface of a base layer BSL to overlap each other. For example, the display area DA may include the circuit layer PCL disposed on the surface of the base layer BSL and the display layer DPL disposed on the circuit layer PCL. However, mutual positions of the circuit layer PCL and the display layer DPL on the base layer BSL may be changed in accordance with embodiments. In case that the circuit layer PCL and the display layer DPL overlap each other in layers separate from each other, each layout space for forming the pixel circuit (see “PXC” shown in FIGS. 3A to 3C) and the light emitting unit (see “EMU” shown in FIGS. 3A to 3C) can be sufficiently secured on a plane.

Circuit elements (e.g., transistors M) constituting a pixel circuit PXC of a corresponding pixel PXL and various types of lines connected thereto may be disposed in each pixel area PXA of the circuit layer PCL. Alignment electrodes ALE, light emitting elements LD, and/or pixel electrodes ELT, which constitute a light emitting unit EMU of a corresponding pixel PXL, may be disposed in each pixel area PXA of the display layer DPL.

The circuit layer PCL may include insulating layers (or insulating films) in addition to the circuit elements and the lines. For example, the circuit layer PCL may include a buffer layer BFL, a gate insulating layer GI, an interlayer insulating layer ILD, and/or a passivation layer PSV, which are sequentially stacked on the surface of the base layer BSL.

The circuit layer PCL may selectively further include a first conductive layer including a bottom metal layer BML and the like, which may be disposed under at least one transistor M (e.g., a first transistor M1).

In an example, the first conductive layer may include a bottom metal layer BML which may be disposed between the base layer BSL and the buffer layer BFL and overlap a gate electrode GE and/or a semiconductor pattern SCP of at least one transistor M (e.g., the first transistor M1).

In an embodiment, the bottom metal layer BML may be connected to one electrode of a corresponding transistor M. In an example, in case that the first transistor M1 includes the bottom metal layer BML, the bottom metal layer BML may be connected to a source electrode (or drain electrode) of the first transistor M1.

The buffer layer BFL may be disposed on the surface of the base layer BSL, on which the first conductive layer may be selectively formed. The buffer layer BFL may prevent an impurity from being diffused into each circuit element.

A semiconductor layer may be disposed on the buffer layer BFL. The semiconductor layer may include a semiconductor pattern SCP of each transistor M, and the like. The semiconductor pattern SCP may include a channel region overlapping a gate electrode GE, and first and second conductive regions (e.g., source and drain regions) disposed at both sides of the channel region. For example, the semiconductor pattern SCP may include an oxide semiconductor.

The gate insulating layer GI may be disposed on the semiconductor layer. A second conductive layer may be disposed on the gate insulating layer GI.

The second conductive layer may include a gate electrode GE of each transistor M. The second conductive layer may further include one electrode of a storage capacitor Cst (see FIG. 3C) and/or a line.

The interlayer insulating layer ILD may be disposed on the second conductive layer. A third conductive layer may be disposed on the interlayer insulating layer ILD.

The third conductive layer may include first and second transistor electrodes TE1 and TE2 of each transistor M. The first and second transistor electrodes TE1 and TE2 may be source and drain electrodes. One of the first and second transistor electrodes TE1 and TE2, e.g., a first transistor electrode of the first transistor M1 may be directly connected to a first connection electrode ALE5 of each light emitting unit EMU through a first contact part CNT1.

The third conductive layer may include a line (e.g., a second power line (see “PL2” shown in FIGS. 3A to 3C) and/or a first power line (see “PL1” shown in FIGS. 3A to 3C).

The second power line PL2 may be directly connected to a second connection electrode ALE6 of each light emitting unit EMU through a second contact part CNT2. Each of the first and second contact parts CNT1 and CNT2 may be configured as a via hole and/or a contact hole, formed in the passivation layer PSV.

In another embodiment, an additional interlayer insulating layer may be disposed on the third conductive layer, and a fourth conductive layer may be disposed on the additional interlayer insulating layer. A line may be disposed on the fourth conductive layer. A bridge pattern may be provided on the first conductive layer, and the first connection electrode ALE5 may be connected to the first transistor electrode TE1 (or second transistor electrode TE2) of the first transistor M1 through the first contact part CNT1 and the bridge pattern.

The position(s) of the first power line PL1 and/or the second power line PL2 may be variously changed in accordance with embodiments. In an example, each of the first and second power lines PL1 and PL2 may be provided in the first conductive layer, the second conductive layer, or the third conductive layer. In case that the first power line PL1 and/or the second power line PL2 have/has a multi-layered structure, the first power line PL1 and/or the second power line PL2 may include multi-layered lines provided in at least two layers among the first to third conductive layers.

The passivation layer PSV may be provided on the third conductive layer. In some embodiments, the passivation layer PSV may include at least an organic insulating layer, and substantially planarize a surface of the circuit layer PCL. The display layer DPL may be disposed on the top of the passivation layer PSV.

The display layer DPL may include a light emitting unit (see “EMU” shown in FIGS. 3A to 3C) of each pixel PXL. For example, the display layer DPL may include alignment electrodes ALE of each pixel PXL, first and second connection electrodes ALE5 and ALE6, light emitting elements LD aligned between the alignment electrodes ALE, and pixel electrodes ELT. In an embodiment, at least some pixel electrodes ELT may be connected to different alignment electrodes ALE through a light blocking pattern LS (or a light blocking layer, a light absorbing pattern, a light absorbing layer, a first insulating layer INS1) or a contact part (or opening) formed in at least one insulating layer.

The display layer DPL may include patterns BNP disposed under the alignment electrode ALE. In an example, the display layer DPL may include patterns BNP located under an of the alignment electrodes ALE to allow the area of each of the alignment electrodes ALE to protrude in an upper direction. The display element DPL may further include at least one conductive layer and/or at least one insulating layer.

For example, the display layer DPL may include patterns BNP, alignment electrodes ALE, a light blocking pattern LS (or a first insulating layer INS1), light emitting elements LD, a second insulating layer INS2, first, second, and fourth pixel electrodes ELT1, ELT2, and ELT4, a third insulating layer INS3, and third and fifth pixel electrodes ELT3 and ELT5.

The patterns BNP may be disposed on the surface of the base layer BSL, on which the circuit layer PCL may be formed. For example, the patterns BNP may be provided on the top of the passivation layer PSV. The patterns BNP may protrude in a height direction of the pixel PXL (e.g., a third direction DR3) on the surface of the base layer BSL. Accordingly, areas of the alignment electrodes ALE disposed on the patterns BNP may protrude upwardly, and the alignment electrodes ALE may have inclined surfaces.

The patterns BNP may include an insulating material including at least one inorganic material and/or at least one organic material. In an example, the patterns BNP may include at least one inorganic layer including various inorganic insulating materials such as silicon nitride (SiNₓ), silicon oxide (SiOₓ), and silicon oxynitride (SiOₓN_{y}). In other embodiments, the patterns BNP may include at least one organic layer including various organic insulating materials such as a photoresist material, and/or be configured with a single- or multi-layered insulator including a combination of organic/inorganic materials.

A reflective wall structure may be formed at the periphery of the light emitting elements LD by the patterns BNP and the alignment electrodes ALE disposed on the top thereof. In an example, in case that the alignment electrodes ALE include a reflective electrode layer, light emitted through first and second end portions EP1 and EP2 of the light emitting elements LD may be reflected by the reflective electrode layer, to be output in an upper direction of each pixel PXL.

The patterns BNP may have various shapes. In an embodiment, the patterns BNP may have an inclined surface inclined at an angle in a range as shown in FIGS. 5A and 5B. In another embodiment, the patterns BNP may have a side surface having a curved shape, a section having a semicircular (or semi-elliptical), or a side surface having a stepped shape with respect to the base layer BSL. Conductive layers (or electrodes) and/or insulating layers, which may be disposed on the top of the patterns BNP, may have a surface profile corresponding to the patterns BNP.

The alignment electrodes ALE may be disposed on the top of the patterns BNP. The alignment electrodes ALE may be disposed to be spaced apart from each other in each emission area EA. In some embodiments, each alignment electrode ALE may have a separated pattern for each pixel PXL. For example, each of first to fourth alignment electrodes ALE1 to ALE4 may have an independent pattern of which both ends are cut in a separation area SPA located at an outer portion of a corresponding pixel area PXA or between adjacent pixel areas PXA.

First and second connection electrodes ALE5 and ALE6 may be formed through the same process as the alignment electrodes ALE.

In some embodiments, each of the first and second connection electrodes ALE5 and ALE6 and the alignment electrodes ALE may have a multi-layered structure including electrode layers. For example, each of the first and second connection electrodes ALE5 and ALE6 and the alignment electrodes ALE may include a first electrode layer and a second electrode layer. One of the first electrode layer and the second electrode layer may have a relatively high reflexibility, and the other of the first electrode layer and the second electrode layer may have a relatively high electrical conductivity (or conductivity). For example, one of the first electrode layer and the second electrode layer may be made of a material having a constant reflexibility to allow light emitted from the light emitting elements LD to advance in the third direction DR3 (or an image display direction of the display device), and the other of the first electrode layer and the second electrode layer may include a low-resistance material to decrease resistance (or contact resistance). For example, the first electrode layer may have a relatively high reflexibility, and include a metal such as silver (Ag), magnesium (Mg), aluminum (Al), platinum (Pt), palladium (Pd), gold (Au), nickel (Ni), neodymium (Nd), iridium (Ir), chromium (Cr), titanium (Ti), or any alloy thereof. For example, the second electrode layer may have a relatively high electrical conductivity, and include a metal such as molybdenum (Mo), titanium (Ti), copper (Cu), aluminum (Al), silver (Ag), or any alloy thereof.

In some embodiments, the light blocking pattern LS (or the first insulating layer INS1) may be disposed on an area of the alignment electrodes ALE and/or the first and second connection electrodes ALE5 and ALE6. For example, the light blocking pattern LS may be formed to cover an area of the alignment electrodes ALE, and include an opening exposing another area of the alignment electrodes ALE (e.g., inclined surfaces facing the first and second end portions EP1 and EP2 of the light emitting elements LD).

As shown in FIGS. 5A and 5B, the light blocking pattern LS may be formed to cover an area of each of the first alignment electrode ALE1 and the third alignment electrode ALE3 between the first pattern BNP1 and the second pattern BNP2, and expose an inclined surface SS1 of the first alignment electrode ALE1 and an inclined surface SS2 of the third alignment electrode ALE3, which face light emitting elements LD. Similarly, as shown in FIG. 5A, the light blocking pattern LS may be formed to cover an area of each of the second alignment electrode ALE2 and the fourth alignment electrode ALE4 between the second pattern BNP2 and the third pattern BNP3, and expose an inclined surface of the second alignment electrode ALE2 and an inclined surface of the fourth alignment electrode ALE4, which face light emitting elements LD. The light blocking pattern LS may not overlap the patterns BNP in a plan view.

To this end, a width W_LS of the light blocking pattern LS in the first direction DR1 may be smaller than or equal to a first distance GAP1 (or first interval) between the patterns BNP. For example, as shown in FIG. 5B, the width W_LS of the light blocking pattern LS in the first direction DR1, which may be disposed between the first pattern BNP1 and the second pattern BNP2, may be smaller than or equal to the first distance GAP1 between the first pattern BNP1 and the second pattern BNP2.

In an embodiment, the light blocking pattern LS may cover an area (or gap) between the alignment electrodes ALE. To this end, the width W_LS of the light blocking pattern LS in the first direction DR1 may be greater than a second distance GPA2 (or second interval) between the alignment electrodes ALE. For example, as shown in FIG. 5B, the width W_LS of the light blocking pattern LS in the first direction DR1, which may be disposed between the first pattern BNP1 and the second pattern BNP2, may be greater than the second distance GAP2 between the first alignment electrode ALE1 and the third alignment electrode ALE3.

The light blocking pattern LS may be formed to cover the first and second connection electrodes ALE5 and ALE6 as shown in FIG. 5C. However, the disclosure is not limited thereto, and the light blocking pattern LS may not be disposed in the separation area SPA (and the non-emission area NEA). In other words, the light blocking pattern LS may be disposed in only the emission area EA.

The light blocking pattern LS (or the first insulating layer INS1) may be primarily formed to entirely cover the alignment electrodes ALE and the first and second connection electrodes ALE5 and ALE6. The light blocking pattern LS may prevent damage of the alignment electrodes ALE or extraction of metal in a subsequent process. After the light emitting elements LD are supplied and aligned on the light blocking pattern LS, the light blocking pattern LS may be partially opened to expose the alignment electrodes ALE. The light blocking pattern LS may have fifth and sixth contact parts CNT5 and CNT6 exposing an area of the first and second connection electrodes ALE5 and ALE6.

However, the disclosure is not limited thereto, and the light blocking pattern LS may be patterned in the form of an individual pattern locally disposed under the light emitting elements LD, after the light emitting elements LD are completely supplied and aligned.

The light blocking pattern LS may be disposed under the light emitting elements LD, to stably support the light emitting elements LD. The light blocking pattern LS may be in contact with the light emitting elements LD (and the alignment electrodes ALE).

In an embodiment, the light blocking pattern LS may include at least one black matrix material (e.g., at least one light blocking material) among various kinds of black matrix materials, and/or a color filter material of a specific color. In an example, the light blocking pattern LS may be formed as a black opaque pattern to block transmission of light.

A majority of light emitted from the light emitting elements LD may be emitted in the upper direction (i.e., the third direction DR3) by the alignment electrodes ALE. A portion of light emitted from the light emitting elements LD may advance in a lower direction (i.e., the opposite direction of the third direction DR3) while being refracted by components (e.g. the pixel electrodes ELT and the third insulating layer INS3 (and insulating layers)) provided in the emission area EA of the pixel PXL. In case that the light advancing in the lower direction is incident onto the semiconductor pattern SCP of the transistor M, the transistor M may be degraded. For example, the semiconductor pattern SCP includes an oxide semiconductor, a defect may occur in an empty space (i.e., oxygen vacancy) in which charges can be freely moved, and the conductivity of the transistor M may increase.

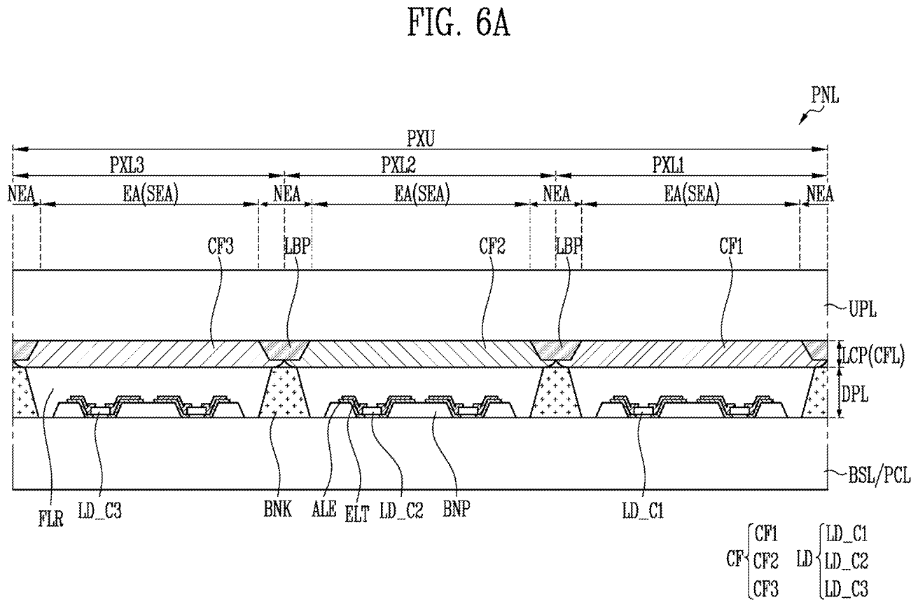

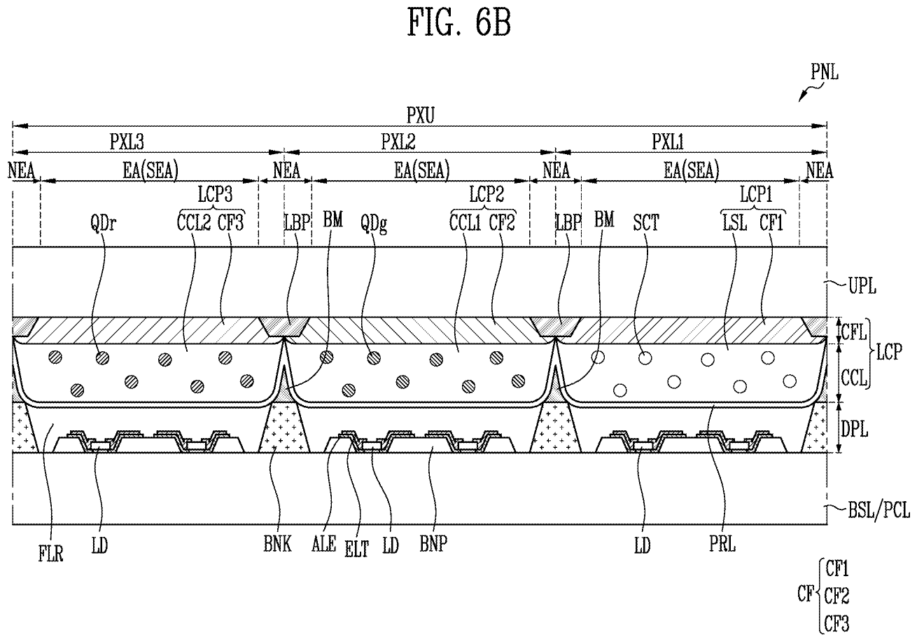

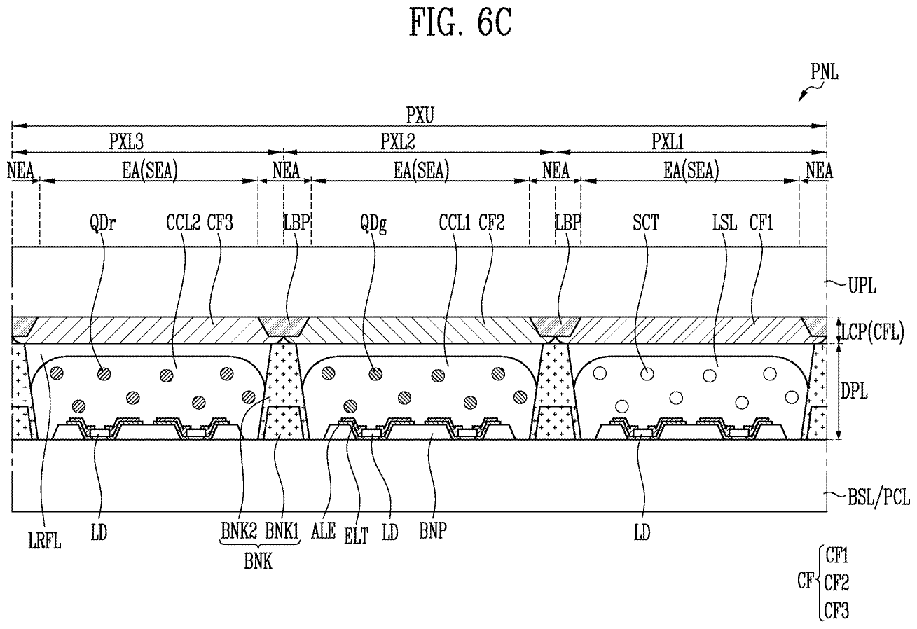

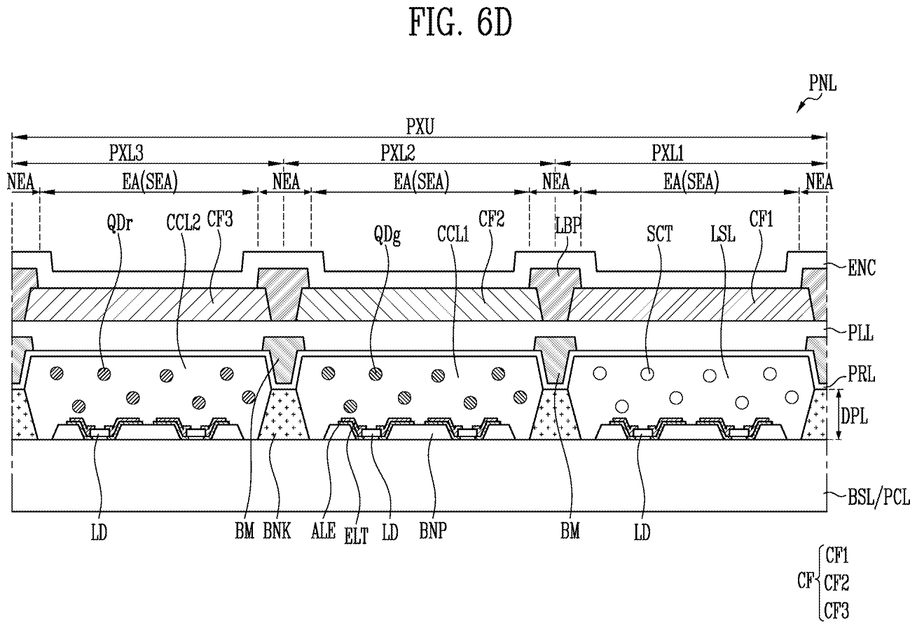

In case that the light emission efficiency of the pixel PXL is not relatively high, the amount of light emitted toward a rear surface may be small, and therefore, the degradation of the transistor M may not be problematic. However, in case that refractive indices of components (e.g., the first to third insulating layers INS1, INS2, and INS3, the pixel electrodes ELT, and a filter (see “FLR” shown in FIG. 6B)) in the pixel so as to improve the light emission efficiency of the pixel PXL, the amount of light emitted toward the rear surface increases, and therefore, the transistor M may be degraded. Thus, the display device DD (see FIG. 2) in accordance with the embodiments of the disclosure includes the light blocking pattern LS disposed to cover the area (or gap) between the alignment electrodes ALE, to block light emitted from the light emitting elements LD and advancing in the lower direction and to prevent the degradation of the transistor M, which may be caused by the light.

A bank BNK may be disposed on the surface of the base layer BSL including the light blocking pattern LS (or the first insulating layer INS1). For example, the bank BNK may be provided in the non-emission area NEA surrounding the emission area EA and the separation area SPA.

The bank BNK may be provided so as not to overlap the fifth and sixth contact parts CNT5 and CNT6. After the bank BNK may be formed, the first and second connection electrodes ALE5 and ALE6 may be easily connected to the first and second pixel electrodes ELT1 and ELT2.

The bank BNK may include an insulating material including at least one inorganic material and/or at least one organic material. In an embodiment, the bank BNK may include a light blocking material or a color filter material, so that the occurrence of light leakage between adjacent pixels PXL can be prevented. The bank BNK may include at least one material among the materials constituting the patterns BNP or include a material different from that of the patterns BNP.

In an embodiment, the bank BNK may have a hydrophobic surface. For example, the bank BNK itself may be formed as a hydrophobic pattern by using a hydrophobic material, or a hydrophobic film made of a hydrophobic material may be formed on the bank BNK, so that bank BNK can be formed to have a hydrophobic surface. In an example, the bank BNK may be formed by using a hydrophobic organic insulating material having a large contact angle, such as polyacrylate. In a process of supplying light emitting elements LD, a light emitting element ink including the light emitting element LD can be prevented from overflowing to the periphery of the emission area EA, and the supply area of the light emitting element ink can be easily controlled.

Light emitting elements LD may be supplied and aligned in each emission area EA. In some embodiments, light emitting elements LD may be supplied to the emission area of each pixel PXL through an inkjet process, a slit coating process or other various processes, and an alignment signal (or alignment voltage) may be applied to each of alignment electrodes ALE (or alignment lines before being separated into the alignment electrodes ALE), thereby aligning the light emitting elements LD between the alignment electrodes ALE. In an example, the light emitting elements LD may be aligned in an area between a pair of patterns BNP located under a pair of alignment electrodes ALE supplied with different alignment signals (e.g., an area between the first and second patterns BNP1 and BNP2, and an area between the second and third patterns BNP2 and BNP3.

In an embodiment, at least some of the light emitting elements LD may be aligned in a lateral direction (or the first direction DR1), an oblique direction (e.g., a direction between the first direction DR1 and the second direction DR2), or the like between a pair of adjacent alignment electrodes ALE such that both end portions (i.e., first and second end portions EP1 and EP2 (see FIG. 4)) in a length direction thereof overlap or may not overlap the pair of alignment electrodes ALE. Both end portions of the light emitting elements LD may be connected to the respective pixel electrodes ELT.

The second insulating layer INS2 (or second insulating pattern) may be disposed on an area of each of the light emitting elements LD. The second insulating layer INS2 may be locally disposed on an area of each of the light emitting elements LD to expose both end portions of each of the light emitting elements LD. For example, the second insulating layer INS2 may be locally disposed on an area of a first light emitting element LD1 to expose both end portions of the first light emitting element LD1, and be locally disposed on an area of a fourth light emitting element LD4 to expose both end portions of the fourth light emitting element LD4. Both end portions of light emitting elements LD, which are not covered by the second insulating layer INS2, may be connected to the respective pixel electrodes ELT. In case that the second insulating layer INS2 may be formed on light emitting elements LD after the light emitting elements LD are completely aligned, the light emitting elements LD can be stably fixed.

In case that a separation space exists between the light blocking pattern LS (or the first insulating layer INS1) and the light emitting elements LD before the second insulating layer INS2 may be formed, the space may be filled by the second insulating layer INS2. Accordingly, the light emitting elements LD can be more stably supported.

The second insulating layer INS2 may include at least one inorganic insulating material and/or at least one organic insulating material. For example, the second insulating layer INS2 may include various kinds of organic/inorganic insulating materials, such as silicon nitride (SiNₓ), and the material constituting the second insulating layer INS2 is not particularly limited.

The first pixel electrode ELT1 may be disposed on a first end portion of the first light emitting element LD1 and the first connection electrode ALE5. The first pixel electrode ELT1 may be in contact with the first end portion of the first light emitting element LD1, and be in contact with the first connection electrode ALE5 through the fifth contact part CNT5. For example, the first pixel electrode ELT1 may electrically connect the first end portion of the first light emitting element LD1 and the first connection electrode ALE5 to each other. In some embodiments, the first pixel electrode ELT1 may also be disposed on an area of the second insulating layer INS2.

The second pixel electrode ELT2 may be disposed on a second end portion of the fourth light emitting element LD4 and the second connection electrode ALE6. The second pixel electrode ELT2 may be in contact with the second end portion of the fourth light emitting element LD4, and be in contact with the second connection electrode ALE6 through the sixth contact part CNT6. For example, the second pixel electrode ELT2 may electrically connect the second end portion of the fourth light emitting element LD4 and the second connection electrode ALE6 to each other.

As described with reference to FIG. 4, the fourth pixel electrode ELT4 may be disposed on a second end portion of the second light emitting element LD2 and a first end portion of a third light emitting element LD3, and electrically connect the second end portion of the second light emitting element LD2 and the first end portion of the third light emitting element LD3 to each other.

The third insulating layer INS3 (or third insulating pattern) may be disposed on the first pixel electrode ELT1 and the second pixel electrode ELT2 (and the fourth pixel electrode ELT4). The third insulating layer INS3 may cover the first pixel electrode ELT1 and the second pixel electrode ELT2 (and the fourth pixel electrode ELT4), and prevent the first pixel electrode ELT1 and the second pixel electrode ELT2 (and the fourth pixel electrode ELT4) from being directly connected to the third pixel electrode ELT3 and the fifth pixel electrode ELT5 (i.e., occurrence of a short circuit). For example, the first pixel electrode ELT1 and the second pixel electrode ELT2 (and the fourth pixel electrode ELT4) may be spaced apart from the third pixel electrode ELT3 and the fifth pixel electrode ELT5 through the third insulating layer INS3.

The third insulating layer INS3 may include at least one inorganic insulating material and/or at least one organic insulating material. For example, the third insulating layer INS3 may include various kinds of organic/inorganic insulating materials, such as silicon nitride (SiNₓ), and the material constituting the third insulating layer INS3 is not particularly limited.

The second and third insulating layers INS2 and INS3 may include different insulating materials. In other embodiments, the second and third insulating layers INS2 and INS3 may include the same insulating material.

The third pixel electrode ELT3 may be disposed on a second end portion of the first light emitting element LD1, and be in contact with the second end portion of the first light emitting element LD1. As described with reference to FIG. 4, the third pixel electrode ELT3 may be disposed on a first end portion of the second light emitting element LD2, and be in contact with the first end portion of the second light emitting element LD2. For example, the third pixel electrode ELT3 may electrically connect the second end portion of the first light emitting element LD1 and the first end portion of the second light emitting element LD2 to each other. In some embodiments, the third pixel electrode ELT3 may also be disposed on an area of the third insulating layer INS3.

The fifth pixel electrode ELT5 may be disposed on a first end portion of the fourth light emitting element LD4, and be in contact with the first end portion of the fourth light emitting element LD4. As described with reference to FIG. 4, the fifth pixel electrode ELT5 may be disposed on a second end portion of the third light emitting element LD3, and be in contact with the second end portion of the third light emitting element LD3. For example, the fifth pixel electrode ELT5 may electrically connect the second end portion of the third light emitting element LD3 and the first end portion of the fourth light emitting element LD4 to each other.

The first to fifth pixel electrodes ELT1 to ELT5 may be made of various transparent conductive materials. In an example, the pixel electrodes ELT may include at least one of various transparent conductive materials (or substances) including indium tin oxide (ITO), indium zinc oxide (IZO), zinc oxide (ZnO), indium gallium zinc oxide (IGZO), indium tin zinc oxide (ITZO), and the like, and be substantially transparent or translucent to satisfy a transmittance. Accordingly, light emitted from both the end portions of the light emitting elements LD can be transmitted through the first to fifth pixel electrodes ELT1 to ELT5 and emitted to the outside of the pixel PXL.

In some embodiments, at least one insulating layer may be further disposed between pixel electrodes ELT and alignment electrodes ALE. The at least one insulating layer may be disposed on the top of the alignment electrodes ALE, to cover the alignment electrodes ALE in at least the emission area EA. The pixel electrodes ELT may be spaced apart from the alignment electrodes ALE by the at least one insulating layer, and at least some of the pixel electrodes ELT may not be electrically connected to the alignment electrodes ALE.

In an embodiment, at least one insulating layer may be provided over the pixel electrodes ELT. For example, an insulating layer may be entirely formed on the display area DA to cover the top of the patterns BNP, the pixel electrodes ELT, the first to third insulating layers INS1, INS2, and INS3, the light emitting elements LD, the pixel electrodes ELT, and the bank BNK. In an embodiment, the insulating layer may include a single- or multi-layered encapsulation layer. In some embodiments, at least one overcoat layer may be further disposed on the top of the insulating layer.

As described above, the light blocking pattern LS may be disposed under the light emitting elements LD between the patterns BNP, and cover the area (or gap) between the alignment electrodes ALE, thereby blocking light advancing between the alignment electrodes ALE. Thus, the degradation of the transistor M can be prevented, which may be caused by light emitted from the light emitting elements LD and advancing in the lower direction.

Although a case where the first and second pixel electrodes ELT1 and ELT2 and the third and fifth pixel electrodes ELT3 and ELT5 are disposed in different layers has been illustrated in FIGS. 5A and 5C, the disclosure is not limited thereto. For example, as shown in FIG. 5D, the first and second pixel electrodes ELT1 and ELT2 and the third and fifth pixel electrodes ELT3 and ELT5 may be disposed in the same layer.

Although a case where the first to third patterns BNP1 to BNP3 are separated from each other has been illustrated in FIGS. 5A to 5C, the disclosure is not limited thereto. For example, as shown in FIG. 5E, first, second, and third patterns BNP1_1, BNP2_1, and BNP3_1 may include a pattern layer BNPL entirely disposed on the passivation layer PSV, and portions at which a top surface of the pattern layer BNPL protrudes in the third direction DR3 may be defined as the first to third patterns BNP1_1 to BNP3_1. The light blocking pattern LS may be disposed on the pattern layer BNPL between the first to third patterns BNP1_1 to BNP3_1. The first to third patterns BNP1_1 to BNP3_1 may be formed through a photo process using a halftone mask. The passivation layer PSV may be omitted.

FIGS. 6A to 6D are schematic sectional views illustrating an embodiment of the display device shown in FIG. 2. For example, FIG. 6A discloses an embodiment of a display panel PNL which may not include color conversion particles (e.g., red and green quantum dots QDr and QDg), and FIGS. 6B to 6D disclose different embodiments of a display panel PNL including the color conversion particles. For example, the display device in accordance with the disclosure may selectively include color conversion particles disposed at an upper portion of each of pixels PXL.

In FIGS. 6A to 6D, a section of the display panel PNL will be illustrated based on an area in which a pixel unit PXU configured with a first pixel PXL1, a second pixel PXL2, and a third pixel PXL3, which may be adjacent to each other, may be disposed. An example structure of each pixel has been disclosed in detail with reference to the above-described embodiments. Therefore, in FIGS. 6A to 6D, the structure of each pixel is schematically illustrated based on alignment electrodes ALE, light emitting elements LD, and pixel electrodes ELT, and its detailed description will be omitted. In an example, FIGS. 6A to 6D schematically illustrate a section of the display panel PNL in a horizontal direction, in which the pixel unit PXU shown in FIG. 2 may be disposed. In the embodiments shown in FIGS. 6A to 6D, components similar or identical to those of the above-described embodiments are designated by like reference numerals, and their detailed descriptions will be omitted.

First, referring to FIGS. 2, 5A, and 6A, a light emitting unit EMU of each pixel PXL may be disposed in a display layer DPL on a base layer BSL and/or a pixel layer PCL. For example, the light emitting unit EMU of the corresponding pixel PXL may be disposed in each emission area EA (or sub-emission areas SEA constituting the emission area EA) of the display layer DPL. In an example, the patterns BNP, the alignment electrodes ALE, the light emitting elements LD, and the pixel electrodes ELT, which are described above, may be disposed in each emission area. At least one insulating layer (e.g., a light blocking pattern LS (or a first insulating layer INS1, second and third insulating layers INS2 and INS3) may be further disposed. An overcoat layer, a filler layer, or the like may be selectively further disposed on the top of the third insulating layer INS3. The structure of the light emitting unit EMU may be variously changed in accordance with embodiments.

A bank BNK surrounding each emission area EA and/or each sub-emission area SEA may be disposed between adjacent emission areas EA and/or sub-emission areas SEA.

In an embodiment, the first, second, and third pixels PXL1, PXL2, and PXL3 may include light emitting elements LD emitting lights of different colors. For example, the first, second, and third pixels PXL1, PXL2, and PXL3 may include first color light emitting elements LD_C1, second color light emitting elements LD_C2, and third color light emitting elements LD_C3, and the first color light emitting elements LD_C1, the second color light emitting elements LD_C2, and the third color light emitting elements LD_C3 may respectively emit light of a first color, a second color, and a third color. In an example, the first color light emitting elements LD_C1 may be blue light emitting elements emitting blue light, the second color light emitting elements LD_C2 may be green light emitting elements emitting green light, and the third color light emitting elements LD_C3 may be red light emitting elements emitting red light.

In some embodiments, an upper substrate UPL may be disposed above the pixels PXL. For example, the upper substrate UPL (also referred to as an “encapsulation substrate” or a “color filter substrate”) encapsulating a display area DA may be disposed on a surface of the base layer BSL on which the pixels PXL may be disposed.

The upper substrate UPL may be a rigid or flexible substrate (or film). In an embodiment, in case that the upper substrate UPL is a rigid substrate, the upper substrate UPL may be a glass substrate, a quartz substrate, a glass ceramic substrate, a crystalline glass substrate, or a combination thereof. In another embodiment, in case that the upper substrate UPL is a flexible substrate, the upper substrate UPL may be a film substrate or a plastic substrate, which may include a polymer organic material. The upper substrate UPL may include fiber glass reinforced plastic (FRP).

The upper substrate UPL may selectively include a light control layer LCP overlapping the pixels PXL. In an example, the light control layer LCP including a color filter layer CFL may be disposed on a surface of the upper substrate UPL, which faces the pixels PXL.

The color filter layer CFL may include a color filter CF corresponding to a color of each pixel PXL. For example, the color filter layer CFL may include a first color filter CF1 disposed above the first pixel PXL1 to allow light generated in the first pixel PXL1 to be selectively transmitted therethrough, a second color filter CF2 disposed above the second pixel PXL2 to allow light generated in the second pixel PXL2 to be selectively transmitted therethrough, and a third color filter CF3 disposed above the third pixel PXL3 to allow light generated in the third pixel PXL3 to be selectively transmitted therethrough. In an embodiment, the first color filter CF1, the second color filter CF2, and the third color filter CF3 may be respectively a blue color filter, a green color filter, and a red color filter, but the disclosure is not limited thereto.

The first color filter CF1 may be disposed between the first pixel PXL1 and the upper substrate UPL, and include a color filter material for allowing light of a first color, which may be generated in the first pixel PXL1, to be selectively transmitted therethrough. For example, in case that the first pixel PXL1 is a blue pixel, the first color filter CF1 may include a blue color filter material.

The second color filter CF2 may be disposed between the second pixel PXL2 and the upper substrate UPL, and include a color filter material for allowing light of a second color, which may be generated in the second pixel PXL2, to be selectively transmitted therethrough. For example, in case that the second pixel PXL2 is a green pixel, the second color filter CF2 may include a green color filter material.

The third color filter CF3 may be disposed between the third pixel PXL3 and the upper substrate UPL, and include a color filter material for allowing light of a third color, which may be generated in the third pixel PXL3, to be selectively transmitted therethrough. For example, in case that the third pixel PXL3 is a red pixel, the second color filter CF2 may include a red color filter material.

A light blocking member LBP may be disposed between the color filters CF. For example, the light blocking member LBP may be disposed on the surface of the upper substrate UPL to face the bank BNK, and overlap an edge of each of the first to third color filters CF1 to CF3. The light blocking member LBP may be opened in an area corresponding to each emission area EA and/or each sub-emission area SEA.

The light blocking member LBP may include at least one black matrix material (e.g., at least one light blocking material) among various kinds of black matrix material, and/or a color filter material of a specific color. The light blocking member LBP may be formed of the same material as the bank BNK, but the disclosure is not limited thereto. For example, the light blocking member LBP and the bank BNK may include the same material or include different materials.

In an embodiment, a filler FLR having a relatively low refractive index may be filled in a space between a bottom plate of the display panel PNL, which includes the base layer BSL, the display layer DPL, and the like, and a top plate of the display panel PNL, which includes the upper substrate UPL, the light control layer LCP, and the like, such that light emitted from the light emitting elements LD can be smoothly emitted in the upper direction of the pixels PXL. In another embodiment, the space between the bottom plate and the top plate of the display panel PNL may be filled with an air layer.

Although an embodiment in which the upper substrate UPL may be disposed on the top of the base layer BSL on which the pixels PXL may be disposed has been disclosed in FIG. 6A, the disclosure is not limited thereto. For example, the color filters CF and the light blocking member LBP may be formed on the surface of the base layer BSL, on which the pixels PXL may be disposed, and the surface of the base layer BSL may be encapsulated by using a thin film encapsulation layer, etc.

Referring to FIG. 6B, the first, second, and third pixels PXL1, PXL2, and PXL3 may include light emitting elements LD emitting light of the same color. For example, all the light emitting elements LD may emit light of the first color. In an example, the light emitting elements LD may emit light of blue, which belongs to a wavelength band of about 400 nm to about 500 nm.

A color conversion layer CCL including at least one kind of color conversion particles may be disposed on at least some pixels PXL among the first, second, and third pixels PXL1, PXL2, and PXL3. Accordingly, the display device in accordance with an embodiment of the disclosure can display a full-color image.

For example, the light control layer LCP may include a color filter layer CFL and/or a color conversion layer CCL, disposed on a surface of the upper substrate UPL to face the pixels PXL. The color conversion layer CCL may be disposed between the color filter layer CFL and the pixels PXL, and include color conversion particles.

Specifically, the light control layer LCP may include a first light control layer LCP1 disposed above the first pixel PXL1, a second light control layer LCP2 disposed above the second pixel PXL2, and a third light control layer LCP3 disposed above the third pixel PXL3. Each of the first, second, and third light control layers LCP1, LCP2, and LCP3 may include a color conversion layer CCL and/or a color filter CF, corresponding to a color.

For example, the first light control layer LCP1 may include a light scattering layer LSL including light scattering particles SCT, and at least one of first color filters CF1 which allow light of the first color to be selectively transmitted therethrough. The second light control layer LCP2 may include a first color conversion layer CCL1 including first color conversion particles corresponding to the second color, and at least one of second color filters CF2 which allow light of the second color to be selectively transmitted therethrough. Similarly, the third light control layer LCP3 may include a second color conversion layer CCL2 including second color conversion particles corresponding to the third color, and at least one of third color filters CF3 which allow light of the third color to be selectively transmitted therethrough.

In an embodiment, the light scattering layer LSL, the first color conversion layer CCL1, and the second color conversion layer CCL2 may be formed the surface of the upper substrate UPL, on which the first to third color filters CF1 to CF3 and the light blocking member LBP may be disposed. A protective layer PRL may be disposed on surfaces of the light scattering layer LSL, the first color conversion layer CCL1, and the second color conversion layer CCL2.

In some embodiments, a pattern capable of blocking light may be additionally disposed between the light scattering layer LSL, the first color conversion layer CCL1, and the second color conversion layer CCL2. For example, a black matrix pattern BM may be disposed between the light scattering layer LSL, the first color conversion layer CCL1, and the second color conversion layer CCL2.

The black matrix pattern BM may include at least one black matrix material (e.g., at least one light blocking material) among various kinds of black matrix material, and/or a color filter material of a specific color. The black matrix pattern BM may be formed of the same material as the bank BNK and/or the light blocking member LBP, but the disclosure is not limited thereto. For example, the black matrix pattern BM, the bank BNK, and/or the light blocking member LBP may include the same material or include different materials.

The display panel PNL having a structure in the light scattering layer LSL, the first color conversion layer CCL, and the second color conversion layer CCL2 may be first formed on a surface of the upper substrate UPL, and the black matrix pattern BM may be formed between the light scattering layer LSL, the first color conversion layer CCL, and the second color conversion layer CCL2, as has been illustrated in the embodiment shown in FIG. 6B. However, the order in which the black matrix pattern BM may be formed may be changed. For example, the black matrix pattern BM may be first formed on the surface of the upper substrate UPL, on which the color filter CF and the like may be disposed, and the light scattering layer LSL, the first color conversion layer CCL1, and/or the second color conversion layer CCL2 may be formed in areas partitioned by the black matrix pattern BM.

In an example, after the black matrix pattern BM may first be formed, the light scattering layer LSL, the first color conversion layer CCL1, and/or the second color conversion layer CCL2 may be formed in the areas partitioned by the black matrix pattern BM through an inkjet process or the like. In other embodiments, in case that it may be unnecessary to first form the black matrix pattern BM according to a process method and/or performance of printing equipment, the black matrix pattern BM may be formed, after the light scattering layer LSL, the first color conversion layer CCL1, and/or the second color conversion layer CCL2 are first formed. For example, the order in which the light scattering layer LSL, the first color conversion layer CCL1, the second color conversion layer CCL2, and/or the black matrix pattern BM are formed and/or the positions or shapes according thereto may be variously changed in accordance with embodiments. The display panel PNL may include or may not include the black matrix pattern BM between the light scattering layer LSL, the first color conversion layer CCL1, and/or the second color conversion layer CCL2.

The light scattering layer LSL may be disposed above the first pixel PXL. In an example, the light scattering layer LSL may be disposed between first light emitting elements LD1 and the first color filter CF1. The light scattering layer LSL may be omitted in accordance with embodiments.

In some embodiments, in case that light emitting elements LD disposed in the first pixel PXL1 are blue light emitting elements emitting blue light, and the first pixel PXL1 is a blue pixel, the light scattering layer LSL may be selectively provided to efficiently use light emitted from the blue light emitting elements. The light scattering layer LSL may include at least one kind of light scattering particles SCT. The first color filter CF1 may be a blue color filter.

For example, the light scattering layer LSL may include light scattering particles SCT dispersed in a matrix material. In an example, the light scattering layer LSL may include light scattering particles SCT such as titanium oxide (TiₓO_{y}) including titanium dioxide (TiO₂), or silica, but the disclosure is not limited thereto. The light scattering particles SCT may not be disposed above only the first pixel PXL1. In an example, the first color conversion layer CCL1 and/or the second color conversion layer CCL2 may selectively include light scattering particles SCT.

In the disclosure, the light scattering layer LSL is not limited to that configured as only a transmission layer for transmission of light and/or a scattering layer for scattering of light. For example, in some embodiments, the light scattering layer LSL may include at least one kind of color conversion particles. In an example, the light scattering layer LSL may include a blue quantum dot.

The first color conversion layer CCL1 may be disposed above the second pixel PXL2, to convert light of the first color, which may be emitted from light emitting elements LD, into light of the second color. To this end, the first color conversion layer CCL1 may be disposed between light emitting elements LD and the second color filter CF2, and include first color conversion particles. In an example, in case that the light emitting elements LD disposed in the second pixel PXL2 are blue light emitting elements emitting blue light, and the second pixel PXL2 is a green pixel, the first color conversion layer CCL1 may include a green quantum dot QDg for converting light of blue, which may be emitted from the blue light emitting elements, into green light. For example, the first color conversion layer CCL1 may include green quantum dots QDg dispersed in a matrix material such as transparent resin. The second color filter CF2 may be a green color filter.

The green quantum dot QDg may absorb blue light and emit green light having a wavelength band of about 500 nm to about 570 nm by shifting a wavelength of the blue light according to energy transition. In case that the second pixel PXL2 is a pixel of another color, the first color conversion layer CCL1 may include a first quantum dot corresponding to the color of the second pixel PXL2.

The first color conversion layer CCL1 may selectively include at least one kind of light scattering particles. For example, the first color conversion layer CCL1 may further include light scattering particles having a kind and/or a material, which may be equal to or different from that of the light scattering particles SCT included in the light scattering layer LSL.

The second color conversion layer CCL2 may be disposed above the third pixel PXL3, to convert light of the first color, which may be emitted from light emitting elements LD, into light of the third color. To this end, the second color conversion layer CCL2 may be disposed between light emitting elements LD and the third color filter CF3, and include second color conversion particles. In an example, in case that the light emitting elements LD disposed in the third pixel PXL3 are blue light emitting elements emitting light of blue, and the third pixel PXL3 is a red pixel, the second color conversion layer CCL2 may include a red quantum dot QDr for converting light of blue, which may be emitted from the blue light emitting elements, into red light. The third color filter CF3 may be a red color filter.

For example, the second color conversion layer CCL2 may include red quantum dots QDr dispersed in a matrix material such as transparent resin. The red quantum dot QDr may absorb blue light and emit red light having a wavelength band of about 620 nm to about 780 nm by shifting a wavelength of the blue light according to energy transition. In case that the third pixel PXL3 is a pixel of another color, the second color conversion layer CCL2 may include a second quantum dot corresponding to the color of the third pixel PXL3.

The second color conversion layer CCL2 may selectively include at least one kind of light scattering particles. For example, the second color conversion layer CCL2 may further include light scattering particles having a kind and/or a material, which may be equal to or different from that of the light scattering particles SCT included in the light scattering layer LSL.

In an embodiment of the disclosure, blue light having a relatively short wavelength in a visible light band may be incident onto the green quantum dot QDg and the red quantum dot QDr, so that absorption coefficients of the green quantum dot QDg and the red quantum dot QDr can be increased. Accordingly, the efficiency of light finally emitted from the second pixel PXL2 and the third pixel PXL3 can be improved, and excellent color reproduction can be ensured. The light emitting unit EMU of each of the first, second, and third pixels PXL1, PXL2, and PXL3 may be configured by using light emitting elements LD of the same color (e.g., blue light emitting elements), so that the manufacturing efficiency of the display device can be improved.

In accordance with the embodiment shown in FIG. 6B, pixels PXL and a display device having the same can be easily manufactured by using light emitting elements LD of a single color (e.g., blue light emitting elements). Further, a color conversion layer CCL may be disposed on at least some pixels PXL, so that a full-color pixel unit PXU and a display device having the same can be manufactured.

Referring to FIG. 6C, the light scattering layer LSL, the first color conversion layer CCL1, and the second color conversion layer CCL2 may be formed on the surface of the base layer BSL, on which the pixels PXL may be formed. For example, the light scattering layer LSL, the first color conversion layer CCL1, and the second color conversion layer CCL2 may be formed on the surface of the base layer BSL to cover the emission area EA of the first, second, and third pixels PXL1, PXL2, and PXL3. In the embodiment shown in FIG. 6C, at least one protective layer (not shown) may also be formed on surfaces of the light scattering layer LSL, the first color conversion layer CCL1, and the second color conversion layer CCL2.

In an embodiment, the bank BNK may be formed more highly to partition areas in which the light scattering layer LSL, the first color conversion layer CCL1, and the second color conversion layer CCL2 are formed. In another embodiment, the bank BNK may be formed with a height to a degree to which an area in which light emitting elements LD are supplied can be partitioned, and an additional pattern (or bank pattern) may be formed on the top of the bank BNK. For example, the bank BNK may include a first bank BNK1 and a second bank BNK2 formed to overlap the first bank BNK1. For example, the bank BNK may be formed as a single layer or a multi-layer, and the structure, position, and/or height of the bank BNK may be variously changed.

Each of the first and second banks BNK1 and BNK2 may include at least one black matrix material (e.g., at least one light blocking material) among various kinds of black matrix material, and/or a color filter material of a specific color. In an example, each of the first and second banks BNK1 and BNK2 may be formed as a black opaque pattern, to block transmission of light. The first and second banks BNK1 and BNK2 may include the same material or include different materials.

The first, second, and third color filters CF1, CF2, and CF3 may be disposed on the upper substrate UPL. For example, the first, second, and third color filters CF1, CF2, and CF3 may be disposed on the surface of the upper substrate UPL to respectively face the light scattering layer LSL, the first color conversion layer CCL1, and the second color conversion layer CCL2.

Referring to FIG. 6D, the light scattering layer LSL, the first color conversion layer CCL1, and the second color conversion layer CCL2, the first to third color filters CF1 to CF3, and the light blocking member LBP may all be formed on the surface of the base layer BSL. For example, the light scattering layer LSL, the first color conversion layer CCL1, and the second color conversion layer CCL2 may be formed on the surface of the base layer BSL, on which the light emitting elements LD and the like are disposed, and a planarization layer PLL may be formed on the light scattering layer LSL, the first color conversion layer CCL1, and the second color conversion layer CCL2.

In some embodiments, the planarization layer PLL may be configured as a single layer or a multi-layer, including at least one organic layer. For example, the planarization layer PLL may include a low refractive organic layer, and accordingly, the light efficiency of the pixel PXL can be ensured.

The first to third color filters CF1 to CF3 and the light blocking member LBP may be formed on a surface of the base layer BSL, on which the planarization layer PLL may be disposed. Subsequently, an encapsulation layer ENC covering the surface of the base layer BSL, on which the first to third color filters CF1 to CF3 and the light blocking member LBP are disposed, may be formed, to encapsulate the display area DA.

In an embodiment, the encapsulation layer ENC may be configured as a single layer or a multi-layer, including at least one organic layer and/or at least one inorganic layer. For example, the encapsulation layer ENC may be configured as a multi-layer including at least one inorganic layer disposed on the surface of the base layer BSL, on which the first to third color filters CF1 to CF3 and the light blocking member LBP may be disposed, and at least one organic layer stacked on the inorganic layer. The encapsulation layer ENC may selectively further include at least one inorganic layer disposed on the organic layer. However, the structure of the encapsulation layer ENC is not limited thereto. For example, in another embodiment, the encapsulation layer ENC may be configured with only inorganic layers of a multi-layer. For example, the material and/or structure of the encapsulation layer ENC may be variously changed in accordance with embodiments.

In at least one embodiment including the embodiment shown in FIG. 6D, the order in which the light scattering layer LSL, the first color conversion layer CCL1, and the second color conversion layer CCL2, and the black matrix pattern BM may be formed, the shape according thereto, and/or whether the black matrix pattern BM is to be formed may be variously changed in accordance with embodiments. For example, when assuming that the light scattering layer LSL, the first color conversion layer CCL1, and/or the second color conversion layer CCL2 may be formed through an inkjet process, the black matrix pattern BM may be first formed according to the performance of inkjet equipment, or the light scattering layer LSL, the first color conversion layer CCL1, and/or the second color conversion layer CCL2 may be formed without forming the black matrix pattern BM. In an example, the display panel PNL may or may not include the black matrix pattern BM (or the bank BNK) between the light scattering layer LSL, the first color conversion layer CCL1, and/or the second color conversion layer CCL2. In some embodiments, the bank BNK and the black matrix pattern BM may be integrated.

Similarly, the order in which the first to third color filters CF1 to CF3 and the light emitting member LBP are formed and/or the shape according thereto may be variously changed in accordance with embodiments. For example, the order in which the first to third color filters CF1 to CF3 and the light emitting member LBP are formed and/or the shape according thereto may be changed according to a method of forming the first to third color filters CF1 to CF3, etc.

In accordance with the embodiments shown in FIGS. 6C and 6D, the light scattering layer LSL, the first color conversion layer CCL1, and the second color conversion layer CCL2 may be formed immediately on the surface of the base layer BSL, on which the light emitting elements LD may be disposed, so that the light efficiency of the pixels PXL can be improved.

In the embodiments shown in FIG. 6B to 6D, it has been described that the first, second, and third pixels PXL1, PXL2, and PXL3 include light emitting elements LD emitting light of the same color, and the color conversion layer CCL may be provided above the first, second, and third pixels PXL1, PXL2, and PXL3. However, the disclosure is not limited thereto. For example, even in case that the first, second, and third pixels PXL1, PXL2, and PXL3 include light emitting elements LD emitting light of different colors as illustrated in the embodiment shown in FIG. 6A, etc., the color conversion layer CCL including at least one kind of color conversion particles may be selectively provided above the first pixel PXL1, the second pixel PXL2, and/or third pixel PXL3.

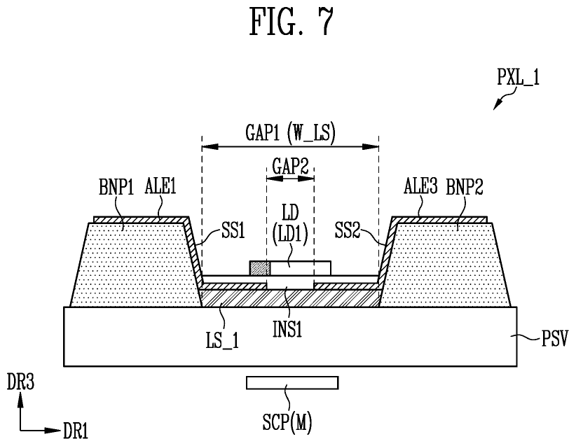

FIG. 7 is a schematic sectional view illustrating another embodiment of the pixel included in the display device shown in FIG. 2. A diagram corresponding to FIG. 5B is illustrated in FIG. 7.

Referring to FIGS. 2, 4, 5A to 5E, and 7, the pixel PXL_1 shown in FIG. 7 may be different from the pixel PXL shown in FIG. 5B, in that the pixel PXL_1 may include a light blocking pattern LS_1 and a first insulating layer INS1 (or first insulating pattern). The pixel PXL_1 shown in FIG. 7 may be substantially identical or similar to the pixel PXL shown in FIG. 5B, except the light blocking pattern LS_1 and the first insulating layer INS1, and therefore, overlapping descriptions may not be repeated. Components (e.g., the circuit layer PCL, the patterns BNP, the alignment electrodes ALE, the pixel electrodes ELT, the second and third insulating layers INS2 and INS3, and the like) of the pixel PXL described with reference to FIGS. 4 and 5A to 5E are omitted, but may be applied to the pixel PXL_1 shown in FIG. 7. The light blocking pattern LS_1 and the first insulating layer INS1, which are shown in FIG. 7, may be applied to the pixel PXL shown in FIGS. 4 and 5A to 5E.

The light blocking pattern LS_1 may be disposed under an area of the alignment electrodes ALE.

As shown in FIG. 7, the light blocking pattern LS_1 may be disposed on the passivation layer PSV between the first pattern BNP1 and the second pattern BNP2. The light blocking pattern LS_1 may not substantially overlap the first pattern BNP1 and the second pattern BNP2 in the third direction DR3 in a plan view. For example, the light blocking pattern LS_1 may not substantially overlap the patterns BNP (see FIG. 4) in a plan view.

A width W_LS of the light blocking pattern LS_1 in the first direction DR1, which may be disposed between the first pattern BNP1 and the second pattern BNP2, may be smaller than or equal to a first distance GAP1 (or first interval) between the first pattern BNP1 and the second pattern BNP2. For example, the width W_LS of the light blocking pattern LS_1 in the first direction DR1 may be smaller than or equal to the first distance GAP1 between the patterns BNP (see FIG. 4).

The alignment electrodes ALE (see FIG. 4) may be disposed on the patterns BNP and the light blocking pattern LS_1. As shown in FIG. 7, the first alignment electrode ALE1 and the third alignment electrode ALE3 may be disposed to overlap a portion of the light blocking pattern LS_1. An area (i.e., a gap) between the first alignment electrode ALE1 and the third alignment electrode ALE3 may overlap the light blocking pattern LS_1. To this end, the width W_LS of the light blocking pattern LS_1 in the first direction DR1 may be greater than a second distance GAP2 (or second interval) between the alignment electrodes ALE (see FIG. 4). For example, as shown in FIG. 7, the width W_LS of the light blocking pattern LS_1 in the first direction DR1, which may be disposed between the first pattern BNP1 and the second pattern BNP2, may be greater than the second distance GAP2 between the first alignment electrode ALE1 and the third alignment electrode ALE3.

In accordance with embodiments of the disclosure, the light blocking pattern LS_1 covers the area (or gap) between the alignment electrodes ALE in the opposite direction of the third direction DR3, and thus light emitted from the light emitting elements LD and advancing in the lower direction may be blocked by the light blocking pattern LS_1. Accordingly, the degradation of the transistor M, which may be caused by the light, can be prevented.

The first insulating layer INS1 may be disposed on at least one area of the alignment electrodes ALE (see FIG. 4). For example, as shown in FIG. 7, the first insulating layer INS1 may be disposed on an area of the first alignment electrode ALE1 and the third alignment electrode ALE3, and expose an inclined surface SS1 of the first alignment electrode ALE1 and an inclined surface SS2 of the third alignment electrode ALE3. However, the first insulating layer INS1 is not limited thereto. For example, the first insulating layer INS1 may be formed to cover the alignment electrodes ALE.

An example will be described with reference to FIG. 4. The first insulating layer INS1 may be primarily formed to entirely cover the alignment electrodes ALE and the first and second connection electrodes ALE5 and ALE6 The first insulating layer INS1 may prevent damage of the alignment electrodes ALE or extraction of metal in a subsequent process. After the light emitting elements LD may be supplied and aligned on the first insulating layer INS1, the first insulating layer INS1 may be partially opened to expose the alignment electrodes ALE. The first insulating layer INS1 may have the fifth and sixth contact parts CNT5 and CNT6 exposing an area of the first and second connection electrodes ALE5 and ALE6.

However, the disclosure is not limited thereto, and the first insulating layer INS1 may be patterned in the form of an individual pattern locally disposed under the light emitting elements LD, after the light emitting elements LD may be completely supplied and aligned.

The first insulating layer INS1 may be disposed under the light emitting elements LD, to stably support the light emitting elements LD.

The first insulating layer INS1 may include at least one inorganic insulating material and/or at least one organic insulating material. For example, the first insulating layer INS1 may include various kinds of organic/inorganic insulating materials, such as silicon nitride (SiNₓ), and the material constituting the first insulating layer INS1 is not particularly limited. The first insulating layer INS1 may include an insulating material different from that of the second and third insulating layers INS2 and INS3 (see FIG. 5A), or include the same insulating material as at least one of the second and third insulating layers INS2 and INS3.

The bank BNK, the second insulating layer INS2, the pixel electrodes ELT, and the second and third insulating layers INS2 and INS3, which are described with reference to FIGS. 4, 5A, and 5C, may be disposed on the first insulating layer INS1.

As described above, the light blocking pattern LS_1 may be disposed under the alignment electrodes ALE between the patterns BNP. The light blocking pattern LS_1 may overlap the area (or gap) between the alignment electrodes ALE, thereby blocking light advancing between the alignment electrodes ALE. Thus, the degradation of the transistor M, which may be caused by light emitted from the light emitting elements LD and advancing in the lower direction, can be prevented.

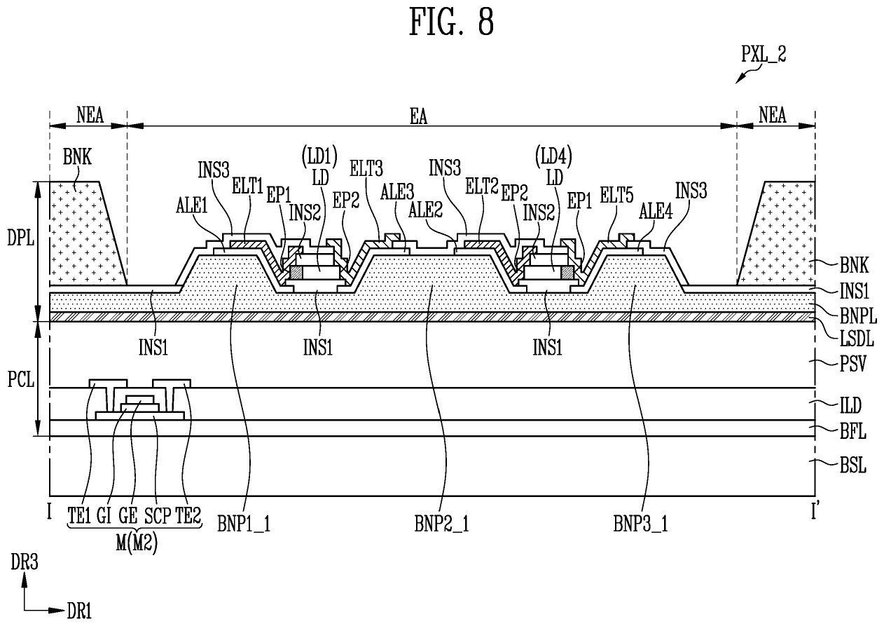

FIG. 8 is a schematic sectional view illustrating still another embodiment of the pixel included in the display device shown in FIG. 2. A diagram corresponding to FIG. 5A is illustrated in FIG. 8.

Referring to FIGS. 2, 4, 5A to 5E, and 8, the pixel PXL_2 shown in FIG. 8 may be different from the pixel PXL shown in FIG. 5E, in that the pixel PXL_2 may include a first insulating layer INS1 and a light blocking layer LSDL. The pixel PXL_2 shown in FIG. 8 may be substantially identical or similar to the pixel PXL shown in FIG. 5E, except the first insulating layer INS1 and the light blocking layer LSDL, and therefore, overlapping descriptions may not be repeated.

The light blocking layer LSDL may be disposed between the pattern layer BNPL and the transistor M. The light blocking layer LSDL may be disposed under the pattern layer BNPL. The light blocking layer LSDL may be entirely disposed on the emission area EA. The light blocking layer LSDL may be disposed to overlap not only the area (or gap) between the first to fourth alignment electrodes ALE1 to ALE4 (or the alignment electrodes ALE (see FIG. 4)) but also the first to third patterns BNP1_1 to BNP3_1 in the third direction DR3.

The light blocking layer LSDL may include at least one black matrix material (e.g., at least one light blocking material) among various kinds of black matrix material, and/or a color filter material of a specific color. In an example, the light blocking layer LSDL may be formed as a black opaque pattern to block transmission of light.

The light blocking layer LSDL may not be separately formed, but the pattern layer BNPL may include a black matrix material. However, the exposure profile (or side surface profile in exposure) of the black matrix material may not be satisfactory, and hence it may be difficult to form contact parts (e.g., the first contact part CNT1 (see FIGS. 4 and 5C) in the pattern layer BNPL (i.e., the pattern layer BNPL including a black matrix material) through a photo process. Therefore, the light blocking layer LSDL may be formed separately from the pattern layer BNPL under the pattern layer BNPL. As described with reference to FIG. 4, the first and second contact parts CNT1 and CNT2 may be formed in the non-emission area NEA and/or the separation area SPA, and therefore, the light blocking layer LSDL may be entirely disposed on the emission area EA. In some embodiments, openings corresponding to the first and second contact parts CNT1 and CNT2 may be formed in the light blocking layer LSDL, and the light blocking layer LSDL may be entirely disposed in the pixel area PXA (see FIG. 4) except the openings.

As described above, the light blocking layer LSDL may be disposed under the pattern layer BNPL (or the first to third patterns BNP1_1 to BNP3_1, and can be entirely disposed on the emission area EA. The light blocking layer LSDL can block light advancing between the alignment electrodes ALE in the emission area EA. Thus, the degradation of the transistor M, which may be caused by light emitted from the light emitting elements LD and advancing in the lower direction, can be prevented.

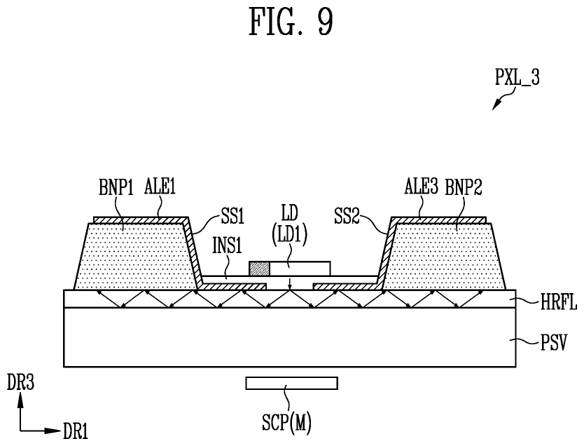

FIG. 9 is a schematic sectional view illustrating still another embodiment of the pixel included in the display device shown in FIG. 2. A diagram corresponding to FIG. 5B is illustrated in FIG. 9.

Referring to FIGS. 2, 4, 5A to 5E, 7, and 9, the pixel PXL_3 shown in FIG. 9 may be different from the pixel PXL shown in FIG. 5B and the pixel PXL_1 shown in FIG. 7, in that the pixel PXL_3 may include a high refractive layer HRFL instead of the light blocking patterns LS or LS_1. The pixel PXL_3 shown in FIG. 9 may be substantially identical or similar to the pixel PXL_1 shown in FIG. 7 except the high refractive layer HRFL, and therefore, overlapping descriptions may not be repeated. Components (e.g., the pixel circuit layer PCL, the patterns BNP, the alignment electrodes ALE, the pixel electrodes ELT, the second and third insulating layers INS2 and INS3, and the like) of the pixel PXL described with reference to FIGS. 4 and 5A to 5E are omitted, but may be applied to the pixel PXL_3 shown in FIG. 9. In other words, the high refractive layer HRFL shown in FIG. 9 may be applied to the pixel PXL shown in FIGS. 4 and 5A to 5E.

The high refractive layer HRFL may be disposed between the transistor M and the first and second patterns BNP1 and BNP2 (or the patterns BNP (see FIG. 4)). The high refractive layer HRFL may be entirely disposed on the passivation layer PSV (or the base layer).

The high refractive layer HRFL may have a refractive index relatively higher than those of adjacent components, and allow incident light to be totally reflected in the high refractive layer HRFL. The amount of light emitted from the light emitting elements LD and advancing in the lower direction may decrease, and thus the degradation of the transistor M, which may be caused by the light, can be prevented or reduced.

The refractive index of the high refractive layer HRFL may be higher than the highest refractive index among refractive indices of the first insulating layer INS1, the passivation layer PSV, and the first and second patterns BNP1 and BNP2. For example, in case that the first insulating layer INS1, the passivation layer PSV, and the first and second patterns BNP1 and BNP2 have a refractive index of about 1.4 to about 1.6 or a refractive index of about 1.47 to about 1.52, the high refractive layer HRFL may have a refractive index higher than about 1.6 or about 1.52.

For example, in order to achieve total reflection made by considering the angle of light incident onto the area (or gap) between the first and third alignment electrodes ALE1 and ALE3 from the light emitting elements LD, the refractive index of the high refractive layer HRFL may be higher by at least about 0.1 or about 0.2 than the highest refractive index among the refractive indices of the first insulating layer INS1, the passivation layer PSV, and the first and second patterns BNP1 and BNP2.

The high refractive layer HRFL may include various kinds of organic/inorganic insulating materials, such as silicon nitride (SiNₓ) and silicon oxide (SiOₓ), and the material constituting the high refractive layer HRFL is not particularly limited.

As described above, the high refractive layer HRFL may be disposed under the patterns BNP and the alignment electrodes ALE, have a refractive index relatively higher than those of adjacent components (e.g., the first insulating layer INS1, the passivation layer PSV, and the first and second patterns BNP1 and BNP2, and allow incident light to be totally reflected therein. The amount of light advancing toward the transistor M while being transmitted through the high refractive layer HRFL may decrease due to total reflection, and the degradation of the transistor M, which may be caused by the light, can be prevented or reduced.

In accordance with the disclosure, the display device may include first and second patterns disposed to be spaced apart from each other, a light emitting element aligned between the first pattern and the second pattern, and a first electrode and a second electrode, which may be respectively disposed on the first pattern and the second pattern, and have inclined surfaces respectively facing end portions of the light emitting element. The display device may include a light blocking pattern or a high refractive layer, which may be disposed under the light emitting element and cover an area (or gap) between the first electrode and the second electrode, and light emitted from the light emitting element and advancing toward a rear surface of the display device may be blocked by the light blocking pattern or be totally reflected by the high refractive layer. Thus, the degradation of an internal element (e.g., a transistor), which may be caused by the light, can be prevented or reduced.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the disclosure as set forth in the following claims, including equivalents thereof.

What is claimed is:

1. A display device comprising:
a first pattern and a second pattern that are spaced apart from each other in an emission area;
a first light emitting element disposed between the first pattern and the second pattern;
a first electrode disposed on the first pattern;
a second electrode disposed on the second pattern; and
a light blocking pattern disposed under the first light emitting element and between the first pattern and the second pattern.

2. The display device of claim 1, wherein the light blocking pattern includes a light blocking material which blocks light emitted from the first light emitting element.

3. The display device of claim 1, wherein
the first pattern and the second pattern are spaced apart from each other in a first direction,
a width of the light blocking pattern in the first direction is greater than a distance in the first direction between the first electrode and the second electrode, and
the width of the light blocking pattern is smaller than a distance in the first direction between the first pattern and the second pattern.

4. The display device of claim 1, wherein
the light blocking pattern is disposed on the first electrode and the second electrode and between the first pattern and the second pattern, and
the light blocking pattern covers an area between the first electrode and the second electrode.

5. The display device of claim 4, wherein
the light blocking pattern does not overlap the first pattern and the second pattern, and
a first inclined surface of the first electrode and a second inclined surface of the second electrode face each other and are exposed by the light blocking pattern.

6. The display device of claim 5, wherein the light blocking pattern extends to the first electrode, the second electrode, and the first light emitting element.

7. The display device of claim 1, wherein each of the first electrode and the second electrode includes a reflective material which reflects light emitted from the first light emitting element.

8. The display device of claim 1, further comprising:
a transistor and a power line that are disposed under the first pattern and the second pattern;
a first pixel electrode electrically connecting a first end portion of the first light emitting element and the transistor to each other; and
a second pixel electrode electrically connecting a second end portion of the first light emitting element and the power line to each other.

9. The display device of claim 8, wherein each of the first pixel electrode and the second pixel electrode includes a transparent conductive material which allows light emitted from the first light emitting element to be transmitted through the first pixel electrode and the second pixel electrode.

10. The display device of claim 8, further comprising:
a bank defining the emission area; and
a color conversion layer disposed on the first light emitting element in the emission area, the color conversion layer converting a color of light emitted from the first light emitting element.

11. The display device of claim 1, wherein
the light blocking pattern is disposed under the first electrode and the second electrode, and
the light blocking pattern overlaps an area between the first electrode and the second electrode.

12. The display device of claim 11, wherein
the light blocking pattern is disposed between the first pattern and the second pattern, and
the light blocking pattern extends to the first electrode and the second electrode.

13. The display device of claim 12, further comprising a first insulating layer disposed between the first light emitting element and the light blocking pattern in an area between the first pattern and the second pattern.

14. The display device of claim 11, further comprising a transistor disposed under the first pattern and the second pattern,
wherein the light blocking pattern is disposed between the first and second patterns and the transistor.

15. The display device of claim 14, wherein
the first pattern and the second pattern are portions of a protective layer at which a top surface of the protective layer protrudes, and
the light blocking pattern is disposed between the protective layer and the transistor.

16. The display device of claim 14, further comprising:
a third pattern spaced apart from the second pattern in the emission area;
a second light emitting element disposed between the second pattern and the third pattern;
a third electrode disposed on the second pattern, the third electrode having an inclined surface facing a first end portion of the second light emitting element; and
a fourth electrode disposed on the third pattern, the fourth electrode having an inclined surface facing a second end portion of the second light emitting element,
wherein the light blocking pattern overlaps an area between the second electrode and the third electrode and an area between the third electrode and the fourth electrode.

17. A display device comprising:
a base layer;
a first pattern and a second pattern that are spaced apart from each other on the base layer in an emission area;
a light emitting element disposed between the first pattern and the second pattern;
a first electrode disposed on the first pattern;
a second electrode disposed on the second pattern; and
an insulating layer disposed under the light emitting element and between the first pattern and the second pattern, wherein
each of the first electrode and the second electrode includes a reflective material which reflects light emitted from the light emitting element, and
a refractive index of the insulating layer is higher than a refractive index of the base layer.

18. The display device of claim 17, wherein the refractive index of the insulating layer is higher than a refractive index of the first pattern and a refractive index of the second pattern.

19. The display device of claim 18, further comprising a first insulating layer disposed between the light emitting element and the insulating layer in an area between the first electrode and the second electrode,
wherein the refractive index of the insulating layer is higher than a refractive index of the first insulating pattern.

20. The display device of claim 18, wherein the insulating layer is disposed in a substantially entire area of the emission area.

21. A display device comprising:
a first electrode having a first inclined surface;
a second electrode having a second inclined surface facing the first inclined surface, the first electrode and the second electrode being spaced apart from each other in an emission area;
a light emitting element disposed between the first inclined surface of the first electrode and the second inclined surface of the second electrode; and
a light blocking pattern disposed under the light emitting element in the emission area.
